(19) United States
(12) Patent Application Publication
(10) Pub. No.: US 2026/0123167 A1
(43) Pub. Date: Apr. 30, 2026

(54) PEROVSKITE PHOTON COUNTING DETECTORS AND USES THEREOF

(71) Applicant: The University of North Carolina at Chapel Hill, Chapel Hill, NC (US)

(72) Inventors: Jinsong HUANG, Chapel Hill, NC (US); Ying ZHOU, Chapel Hill, NC (US)

(21) Appl. No.: 19/472,449

(22) PCT Filed: Apr. 3, 2024
(86) PCT No.: PCT/US2024/022806

§ 371 Date: Oct. 3, 2025

Related U.S. Application Data
(60) Provisional application No. 63/494,207, filed on Apr. 4, 2023.

(51) Int. Cl. H10K 30/88; H10K 30/60; H10K 85/50

(52) U.S. Cl. CPC H10K 30/88; H10K 30/60; H10K 85/50

(57) ABSTRACT

As described herein, the dark count rate (DCR) of perovskite photon-counting detectors (PCDs) was dominated by charge de-trapping from shallow traps located at the grain boundaries and surface, and the ultra-low DCR was achieved by suppressing the shallow traps by enhancing grain size and passivating film surface with diphenyl sulfide. The suppression of shallow traps made the perovskite PCDs have 100-1000 times lower DCR and much better response linearity to weak light than SiPMs. and the DCR was not sensitive to temperature due to small activation energy of charge traps. The zero-bias operating perovskite PCDs were demonstrated as γ-ray spectrum detectors with better energy resolution under ⁵⁷Co source than commercial SiPMs at room temperature. At higher temperature up to 85° C. the perovskite PCDs are much superior to SiPMs by maintaining the energy resolution, showing their potential of working in harsh environment. This study discovered regular surface passivation also dramatically impact shallow charge traps, which should have implication of perovskite stability and doping.

### CROSS REFERENCE TO RELATED APPLICATIONS

This application claims the benefit of priority to U.S. Provisional Application No. 63/494,207, filed Apr. 4, 2023, which is herein incorporated by reference in its entirety.

### STATEMENT OF GOVERNMENT SUPPORT

This invention was made with government support under Grant. No. HDTRA1-20-2-0002 awarded by the Department of Defense. The government has certain rights in the invention.

### FIELD OF INVENTION

The presently disclosed subject matter relates generally to polycrystalline perovskite precursor compositions and films for use in photon counting applications with enhanced capabilities.

### BACKGROUND

Metal halide perovskites have found broad applicability in the conversion of photons to electric current or vice versa in solar cells (PSCs), light emitting diodes (LEDs), and solar fuels. The subject matter described herein is directed to the development of metal halide perovskites as photodetectors. Various spectrometric applications can benefit from enhanced performance of solid-state photon-counting detectors (PCDs). However, the photomultipliers that are widely used for this purpose, silicon photomultipliers and vacuum-based photomultiplier tubes, often require high bias, have high dark count rates, are not reliably suited for use in harsh environments such as high temperatures, and/or are susceptible to magnetic fields. As such, novel solid-state photon counting detectors (PCDs) with low dark count rates (DCR), high detection probabilities, low working bias, and radiation stability would benefit various spectrometric application such as light detection and ranging (LiDAR), radiation spectroscopy, quantum optics, flow cytometry, etc. The subject matter described herein addresses this unmet need.

### BRIEF SUMMARY

In one aspect, the presently disclosed subject matter is directed to a multilayer perovskite composite comprising:
a polycrystalline perovskite film comprising a composition of Formula (I):

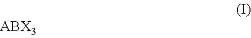

wherein A is a cation selected from the group consisting of methylammonium (MA), tetramethylammonium (TMA), formamidinium (FA), cesium (Cs), rubidium (Rb), potassium (K), sodium (NA), butylammonium (BAH), phenylethylammonium (PEA), phenylammonium (PHA), guanidinium (GU), and a combination thereof;
B is at least one divalent metal; and
X is at least one halide;
   and,
a passivating layer disposed on at least a portion of a surface of said polycrystalline perovskite film;
   wherein said passivating layer comprises an organosulfide material.

In another aspect, the presently disclosed subject matter is directed to a method of preparing a multilayer perovskite composite comprising:
disposing a precursor passivating solution comprising an organosulfide material and a solvent onto a surface of a polycrystalline perovskite film using a fast-coating process, wherein a passivating layer forms on said surface of the polycrystalline perovskite film, and said passivating layer comprises an organosulfide material.

In another aspect, the presently disclosed subject matter is directed to a perovskite photon counting detector, comprising:
one or more transparent conductive oxide layer;
one or more conductive electrode layer; and
an active layer comprising the multilayer perovskite composite disclosed herein.

In another aspect, the presently disclosed subject matter is directed to a photon counting device. The photon counting device, comprising:
a neutral density filter;
the perovskite photon counting detector according to the embodiments described herein.
a charge sensitive pre-amplifier;
a shaping amplifier; and
a multichannel analyzer.

In another aspect, the subject matter described herein is directed to a method of counting photons, comprising:
exposing the perovskite photon detector according to the embodiments disclosed herein to a number of incident photons as controlled by a neutral density filter;
wherein an output signal is generated the perovskite photon counting detector and is amplified by a charge sensitive preamplifier and a shaping amplifier; and
wherein the amplified signal is analyzed and reported as histograms of photon counts by a multichannel analyzer.

### BRIEF DESCRIPTION OF THE DRAWINGS

FIGS. 1A-1C describe the origin of dark counts and photon counting performance. DCR contribution illustration for PCDs operated at high reverse bias for (A) SiPMs, (B) Zero bias for perovskite PCDs. The band tilting is not drawn in scale. (C) Output signal histograms of a typical MAPbI3 solar cell under incident light pulses with different photon numbers per pulse. The channel number is proportional to the extracted charges.

FIGS. 2A-2B describe device performance of a typical FA_{0.7}MA_{0.3}PbI₃ solar cell. (A) typical J-V curve of FA_{0.7}MA_{0.3}PbI₃ solar cell. (B) photon counting performance of the FA_{0.7}MA_{0.3}PbI₃ solar cell.

FIG. 3 depicts a schematic diagram of the photon counting measurement system, CSP is charge sensitive preamplifier.

FIGS. 4A-4L describe the suppression of the dark count rate (DCR) of perovskite photon counting detectors (PCDs). (A) Schematic illustration of surface defect passivation by diphenyl sulfide. Top-view SEM images of (B) One-step processed MAPbI₃ film and (C) Two-step processed MAPbI₃ film. The scale bar is 500 nm. Cross-sectional SEM images of (D) One-step processed MAPbI₃ film and (E) Two-step processed MAPbI₃ film. Scale bar is 500 nm. (F) PL and (G) TRPL of MAPbI₃ films on glass substrates. (H) Trap density at different profiling distance in the perovskite PCDs measured by DLCP at an AC frequency of 50 kHz. (I) Dark count rate of perovskite PCDs. (J) Temperature dependent DCR of perovskite PCDs. (K) The shunting resistance and corresponded DCR of 32 one-step device, 30 two-step device, and 32 two-step devices with passivation. Each data point represents one device. (L) The ratio of DCR of each device biased at −0.1 V and 0 V.

FIGS. 5A-5B display SEM images of perovskite films. (A) without and (b) with diphenyl sulfide surface passivation. Scale bar is 500 nm.

FIGS. 6A-6B describe the optical properties of MAPbI₃ films. (A) PL spectra and (B) TRPL of MAPbI₃ films on glass deposited by one-step process with and without diphenyl sulfide passivation.

FIGS. 7A-7b display the photon counting property of one-step MAPbI₃ device. (A) photon counting performance of one-step processed MAPbI₃ with diphenyl sulfide passivation. (B) DCR of one-step processed MAPbI₃ devices with and without diphenyl sulfide passivation.

FIG. 8 depicts the XRD patterns of MAPbI₃ films.

FIGS. 9A-9B describe the photon counting performance of two-step MAPbI₃ devices with various concentrations of passivation material. (A) Response for 11511 photons/pulse (B) EQE of devices with various diphenyl sulfide surface passivation concentration.

FIG. 10 displays the tDOS of the perovskite PCDs as measured by TAS.

FIG. 11 displays the temperature dependent DCR of the two step (top) and passivated two step (bottom) perovskite PCDs.

FIG. 12 displays the temperature dependent DCR of the passivated two-step perovskite PCD.

FIGS. 13A-B displays the shunt resistance of the perovskite PCDs. (A) Dark current curves of the one-step, two-step and passivated two-step MAPbI₃ devices. The solid lines are the fitting lines to extract the shunt resistance. The shunt resistances of one-step, two-step, and passivated two-step MAPbI₃ devices is 10,964 MΩ mm², 8,887 MΩ2 mm² and 9,523 MΩ mm², respectively. The I-V′ curves for shunting resistance determination were acquired by a Keithley 4200A-SCS in the dark. (B) Noise floor of the I-I′ measurement system. The noise floor was measured by removing the device to sweep the I-V measurement.

FIGS. 14A-14D describe the photon counting performance of the perovskite detector. (A) Output signal histograms of zero-biased perovskite PCD and SiPM operating at 29 V under the various number of incident photons per pulse. The unit is photons/pulse. (B) Channel number of the photopeak at different incident photon numbers per pulse. (C) Internal quantum efficiency of the perovskite PCD at different incident photons per pulse. (D) Pulse detection probability of the perovskite PCD and the SiPM.

FIGS. 15A-15F describe the performance of a silicon diode (S2387 from Hamamatsu). (A) A photograph of the silicon S2387 diode; (B) Photo and dark current density curves of the Si photodiode. (C) EQE of the Si photodiode. (D) Shunting resistance of the photodiode. (E) Dark count rate collected for the photodiode detector for 60 s measured at zero bias. (F) Output of the Si diode measured at zero bias under incident light pulse with photon numbers. The light source for the photon counting performance measurement is a 630 nm picosecond pulse laser from Horiba.

FIGS. 16A-16F describe the performance of a monocrystalline GaAs photodetector. (A) A photograph of the single crystalline GaAs solar cells. (B) Photo and dark current density curves of the GaAs solar cell; (C) EQE of the GaAs solar cells. (D) Shunting resistance of the GaAs solar cells. (E) Dark count rate collected for the GaAs detector for 60 s measured at zero bias. (F) Output of the GaAs detectors measured at zero bias under incident light pulse with photon numbers upto 260,383. The light source for the photon counting performance measurement is a 630 nm picosecond pulse laser from Horiba.

FIGS. 17A-17F describe the performance of a InGaN PN diode (GVGR-T11GD from GENUV, Inc.) (A) A photograph of the InGaN diode. (B) Photo and dark current density curves of the InGaN diode. (C) EQE of the InGaN diode. (D) shunting resistance of the InGaN photodiode. (E) Dark count rate collected for the detector for 60 s measured at zero bias; (F) Output of the InGaN diode measured at zero bias under incident light pulse with photon numbers. The light source for the photon counting performance measurement is a 404 nm picosecond pulse laser from Horiba.

FIGS. 18A-18D describe the perovskite PCDs' γ-ray spectroscopy performance. (A) ⁵⁷Co γ-ray spectra collected by the perovskite PCD and the SiPM under the same experimental conditions. ¹³⁷Cs γ-ray spectra collected by (B) the perovskite PCD and (C) the SiPM, and (D) Energy resolution at 662 keV resolved by the perovskite PCD and the SiPM at different temperatures.

FIG. 19 displays the spectra collected by two types of PCDs. ¹³⁷Cs γ-ray spectra collected by the perovskite PCD at zero bias and SiPM at 29 V under the same experimental conditions.

FIGS. 20A-20D describe the stability of perovskite PCDs. The tracking of (A) DCR, (B) the output histogram peak channel number under continuous 25685 photons/pulse. (C) Pulse detection probability for incident photon number of 25685 per pulse of the perovskite PCD at zero bias and the SiPM at 29 V. (D) the ¹³⁷Cs γ-ray spectrum energy resolution resolved by the perovskite PCD coupled with CsI(Tl) at zero bias.

FIG. 21 displays the stability study of the perovskite PCDs. ¹³⁷Cs γ-ray spectra collected by the perovskite PCD at zero bias under the same experimental conditions once per week in 8 weeks.

### DETAILED DESCRIPTION

Described herein are multilayer perovskite composites having a passivating layer comprising an organosulfide compound. Also described herein are photon counting detectors (PCDs) having a multilayer perovskite composite with a passivating layer and methods for forming a passivating layer comprising an organosulfide compound on a perovskite film. Also described herein are methods and characteristics of electronic devices prepared from the multilayer perovskite composite described herein.

The presently disclosed subject matter will now be described more fully hereinafter. However, many modifications and other embodiments of the presently disclosed subject matter set forth herein will come to mind to one skilled in the art to which the presently disclosed subject matter pertains having the benefit of the teachings presented herein. Therefore, it is to be understood that the presently disclosed subject matter is not to be limited to the specific embodiments disclosed and that modifications and other embodiments are intended to be included within the scope of the appended claims. In other words, the subject matter described herein covers all alternatives, modifications, and equivalents. Unless otherwise defined, all technical and scientific terms used herein have the same meaning as commonly understood by one of ordinary skill in this field. All publications, patent applications, patents, and other references mentioned herein are incorporated by reference in their entirety. In the event that one or more of the incorporated literature, patents, and similar materials differs from or contradicts this application, including but not limited to defined terms, term usage, described techniques, or the like, this application controls.

### I. Overview

Emerging applications such as light detection and ranging (LiDAR), radiation spectroscopy, quantum optics, flow cytometry, and many others stand to benefit from advancement of solid-state photon-counting detectors (PCDs) with low dark count rate (DCR), high detection probability, low working bias, large linear dynamic range, radiation stability, lightweight, and compact size.¹⁻⁵ Silicon photomultipliers (SiPMs) are the dominating solid-state photodetectors challenging vacuum-based photomultiplier tubes (PMTs) due to their comparably high gains. The solid-state SiPMs avoid the magnetic susceptibility of PMTs, and operate at much lower bias of tens of volts.^{6, 7} These compact and small size detectors can be made into arrays.⁸ Therefore, they are now widely commercially available and becoming increasingly popular for photon-counting applications. However, the high DCR from thousand to million counts per second per square millimeter (cps/mm²) of SiPMs is still a contemporary problem that significantly limits their applications, particularly in harsh environments⁹ The dark counts in SiPMs are caused by avalanche triggered by background carriers which undergo the same process as the photogenerated carriers and therefore are amplified. One main source of the background charge carriers is from band-to-band tunneling process.¹⁰ Despite the much lower bias, the electric field in avalanching layer of SiPMs is still very high and thus can drive electrons in valance band through to the conduction band, which constitutes a major source of dark counts at low temperature.¹¹ At temperature above 200 K, the band-to-band thermal excitation of electrons dominates background free carriers due to the relatively narrow bandgap of silicon. DCR doubles for every temperature increase by 8 K.¹² Therefore, cooling is usually needed to attain the best performance of SiPMs.

Metal halide perovskites (MHPs) have shown great potential in applications of solar cells, light emitting diodes, photodetectors, ionization radiation detectors, solar fuels, etc.¹³⁻¹⁷ These materials are very diversified with tunable compositions and dimensionality, which dramatically enrich material design and selection possibilities. The versatile material synthesis methods, including vapor-based growth, solution growth, or their combinations, allow the fabrication of MHPs with desired material morphology, size, throughput, and form factors to meet different application needs.^{18, 19} These applications leverage the many unique optoelectronic properties of MHPs, such as very long charge recombination lifetime, large carrier mobilities, strong absorption to ultraviolet and visible (UV-Vis) and near infrared (NIR) light or attenuation to X-ray.²⁰⁻²³ Lead-based perovskites have a bandgap much larger than that of silicon, which can dramatically reduce the device noise. Very sensitive photodetectors have been demonstrated using both polycrystalline and single crystalline perovskites with a lowest detectable steady-state light intensity reaching picowatt per square centimeter (pW/cm²).^{24, 25} Though their sensitivities are already comparable or superior to the best commercially available silicon photodiodes, the perovskite photodetectors have not been demonstrated for photon counting yet. One challenge comes from the high migration rate of some ions in MHPs, preventing a reverse bias of even a few volts to be applied on these devices.

The subject matter described herein is directed to self-powered perovskite PCDs with extremely low dark counts rate. Shallow traps, which do not limit charge collection efficiency, contribute to the high DCR in perovskite PCDs. By dramatically reducing these charge traps by morphology controlling and defect passivation, self-powered perovskite PCDs with an ultra-low DCR of 2 cps/mm² at room temperature can be fabricated. The detectors achieved >99.8% pulse detection probability, and an internal quantum efficiency (IQE) of 95±5% for several hundred to several hundred million incident photons. As a demonstration, perovskite PCDs were applied to collect gamma-ray (γ-ray) spectra in combination with scintillators, resulting in better energy resolution than commercial SiPMs at room temperature and higher temperatures.

### II. Definitions

As used herein, “and/or” refers to and encompasses any and all possible combinations of one or more of the associated listed items, as well as the lack of combinations when interpreted in the alternative (“or”).

As used herein, the term “about,” when referring to a measurable value such as an amount of a compound or agent of the current subject matter, dose, time, temperature, and the like, is meant to encompass variations of ±20%, ±10%, ±5%, ±1%, +±0.5%, or even ±0.1% of the specified amount.

As used herein, conditional language used herein, such as, among others, “can,” “could,” “might,” “may,” “e.g.,” and the like, unless specifically stated otherwise or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without author input or prompting, whether these features, elements and/or steps are included or are to be performed in any particular embodiment. The terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list.

As used herein, the terms “incident light” or “incident photons” refer to light or photons that fall on the surface of a material. Incident light can be from natural lighting, like the sun, or from an artificial light source. Incident light can also be light that reflects off another surface, such as a reflector, on to the surface of the material of interest.

As used herein, the terms “photodetector,” “photon count detector,” or “photon counting detector” and variations thereof refer to a semiconductor device that absorbs light energy in photons and converts this light energy into electric current or signals.

As used herein, the term “bias” refers to a fixed direct current (DC) applied to a terminal of an electronic component in a circuit in which time-varying (AC) signals are also present, in order to establish proper operating conditions for the component. As used herein, the term “zero bias” is used to describe an electronic component, such as a p-i-n semiconductor or a p-n junction, in which no external voltage is applied to establish proper operating conditions.

As used herein, the terms “photomultipliers,” “photomultiplier tubes,” “PMTs,” and variations thereof refer to devices that are extremely sensitive detectors of light in the ultraviolet, visible, and near-infrared ranges of the electromagnetic spectrum. These detectors multiply the current produced by incident light by as much as 100 million times (i.e. 10⁸). Photomultipliers allow for the detection of individual photons even when the incident flux is low. Vacuum photomultipliers comprise a photocathode, several dynodes, and an anode. Incident photons strike the photocathode, and primary electrons are emitted from the surface of the photocathode; these electrons are directed towards the electron multiplier which comprises several dynodes held at sequentially increasing positive potentials. The primary electrons undergo secondary emission as they bounce from dynode to dynode, leading to a cascade of electrons and a resultant overall gain (electron multiplication) to the order of a million or more. This large number of electrons reaching the anode results in a sharp current pulse that is easily detectable. Photomultiplier tubes typically utilize 1000 to 2000 volts to accelerate electrons within the chain of dynodes. The most negative voltage is connected to the photocathode, and the most positive voltage is connected to the anode. The high voltage at the photocathode often causes leakage currents which result in unwanted “dark current” pulses that may affect the operation of the PMT. PMTs also must be shielded from ambient light to prevent their destruction through overexcitement. Additionally, strong magnetic fields can curve electron paths and steer the electrons away from the dynodes and loss of gain.

As used herein, the terms “silicon photomultipliers,” “SiMPs,” and variations thereof refer to solid-state single-photon-sensitive photodetector devices. SiMPs comprise an array of hundreds or thousands of self-quenched single-photon avalanche diodes (SPADs, also referred to as microcells or pixels) in parallel on silicon substrates. The dimension of each single SPAD can vary from 10 to 100 μm. A photo-generated charge carrier is accelerated by the electric field in the device to a kinetic energy which is enough to overcome the ionization energy of the bulk material, knocking electrons out of an atom. A large avalanche of current/charge carriers grows exponentially until quenched and can be triggered from as few as a single photon-initiated carrier. Once the avalanche is quenched, the microcells reset. The time between quenching of the avalanche and microcells resetting to be able to detect another incoming photon is referred to as recovery time. The bias voltage required for SiMPs varies between 20V and 100V, being approximately 15 to 75 times lower than the voltage require for traditional PMT operation. The photon detection efficiency of SiPMs ranges from 20-50%, depending on the device characteristics and the wavelength of light, which is similar to that of a traditional PMT. Gain of electrons in a SiMP is also similar to a PMT. Unlike traditional PMTs, the signal parameters are practically independent of external magnetic fields. However, SiPMs are plagued with dark current at any given temperature, thereby often requiring subambient cooling of the SiPMs. Furthermore, SiPM usage for larger matrices and/or signal amplification requires optimization because large active areas necessitates higher dark counts per unit area.

As used herein, the terms “dark count(s)” or “dark current(s)” refer to the current or charge carriers (holes and electrons) generated in photosensitive devices in the absence of incident light or when no photons enter the device. Physically, the dark counts or dark current occurs due to random generation of electrons and holes within the depletion region of the device. The rate of rate may be related to specific crystallographic defects within the depletion region and/or to thermal generation of charge carriers as opposed to photo-induced generation of carriers.

As used herein, the term “valence band” refers to the range of highest energy electronic states where electrons are normally present at absolute zero. The electrons in the valence band are held in place until acted upon by an external source, such as thermal or light energy.

As used herein, the term “conduction band” refers to the range of lowest energy electronic states that are vacant at absolute zero. Electrons in the conduction band can move freely to conduct electric current.

As used herein, the term “hole” refers to an empty state left behind by an electron that acquired sufficient energy to jump into the conduction band of a conductor or semiconductor material. The presence of holes in a valence band allows the electrons therein some degree of freedom and conductivity. As such, both electrons and electron holes serve as charge carriers in a semiconductor material.

As used herein, the term “defect” refers to a defective site in a crystal lattice where the local crystal structure does not correspond to the crystal structure of the bulk material. Non-limiting examples of defective sites include point defects, line defects, and planar defects. Point defects include vacancy defects (the absence of an ion), interstitial defects (the interstitial inclusion of an additional ion), Frenkel defects (a closely located pair of defects consisting of an interstitial defect and a vacancy defect) and the presence of an impurity ion. Planar defects include grain boundaries and stacking faults.

As used herein, the term “p-i-n perovskite structure” or “p-i-n planar structure” refers to perovskite films wherein the film is illuminated through the hole transport layer (HTL) side. Alternately, the term “n-i-p perovskite structure” refers to perovskite films wherein the film is illuminated through the electron transport layer (ETL) side.

As used herein, the term “grain” refers to a small region of crystalline or polycrystalline material having a specific and continuous crystal lattice orientation. Each grain represents a small single crystal.

As used herein, the term “shunt,” “shunting resistance,” “shunting,” or variations thereof refer to the inclusion a low-resistance path for electrical current and allow it to pass another point in the circuit. In photovoltaic applications, shunting resistance can cause significant power losses; this resistance arises typically due to manufacturing defects. Low shunt resistance causes power losses by providing an alternate current path for the light-generated current, effectively reducing the amount of current that passes through the photovoltaic junction and reduces the overall voltage. In low light levels, such as those used in photon counting applications, the effect of a shunt resistance is particularly severe as there is less light-generated current. The loss of this current to the shunt bears a greater impact.

As used herein, the term “neutral density filter” applies to filters of light that are used to equally attenuate the intensity of a light beam over a wide wavelength range.

As used herein, the term “charge sensitive preamplifier” or “CSP” refers to an electronic device that can integrate a signal current and generate a voltage signal with an amplitude proportional to the incoming input charge.

As used herein, the term “shaping amplifier” refers to an amplifier that accepts a step-like input pulse and produces an output pulse shaped like a Gaussian function (bell curve).

As used herein, the term “multichannel analyzer” or “MCA” refers to an instrument that records incoming pulses and stores information about the pulses in one of two modes. The pulse-height analysis mode (PHA mode) characterizes the incoming pulses based on their amplitude (peak voltage). The output spectrum is a histogram of these pulses, wherein the height of each channel corresponds to the number of pulses counted within a narrow range of amplitudes. Alternately, the multichannel scaling mode (MCS mode) records a pulse count-rate over time. MCS does not differentiate pulses of different amplitudes, but records all measure counts in one channel for a set time interval, then switches to the next channel to record subsequent time intervals.

As described herein, the term “multilayer” refers to a composite material comprises two or more distinct layers.

### III. Multilayer Perovskite Composites

In embodiments, the subject matter described herein is directed to multilayer perovskite composite comprising:
a polycrystalline perovskite film comprising a composition of Formula (I):

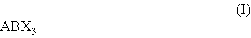

wherein A is a cation selected from the group consisting of methylammonium (MA), tetramethylammonium (TMA), formamidinium (FA), cesium (Cs), rubidium (Rb), potassium (K), sodium (NA), butylammonium (BAH), phenylethylammonium (PEA), phenylammonium (PHA), guanidinium (GU), and a combination thereof;
B is at least one divalent metal; and
X is at least one halide;
   and,
a passivating layer disposed on at least a portion of a surface of the polycrystalline perovskite film;
   wherein said passivating layer comprises an organosulfide material.

In embodiments described herein, the organosulfide material is a compound of Formula (II):

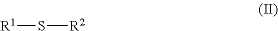

wherein R¹ and R² are each independently selected from the group consisting of (C₁-C₆) alkyl, cycloalkyl, and aryl.
   a. Compositions of Formula (I)

Described herein are compositions of Formula (I):

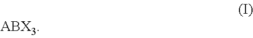

In certain embodiments of the perovskite film, A may comprise an ammonium, an organic cation of the general formula [NR₄]⁺ where the R groups can be the same or different groups. Suitable R groups include, but are not limited to: methyl, ethyl, propyl, butyl, pentyl group or isomer thereof; any alkane, alkene, or alkyne CₓH_{y}, where x=1-20, y=1-42, cyclic, branched or straight-chain; alkyl halides, CₓH_{y}X_{z}, x=1-20, y=0-42, z=1-42, X=F, Cl, Br, or I; any aromatic group (e.g., phenyl, alkylphenyl, alkoxyphenyl, pyridine, naphthalene); cyclic complexes where at least one nitrogen is contained within the ring (e.g., pyridine, pyrrole, pyrrolidine, piperidine, tetrahydroquinoline); any sulfur-containing group (e.g., sulfoxide, thiol, alkyl sulfide); any nitrogen-containing group (nitroxide, amine); any phosphorous containing group (phosphate); any boron-containing group (e.g., boronic acid); any organic acid (e.g., acetic acid, propanoic acid); and ester or amide derivatives thereof; any amino acid (e.g., glycine, cysteine, proline, glutamic acid, arginine, serine, histidine, 5-ammoniumvaleric acid) including alpha, beta, gamma, and greater derivatives; any silicon containing group (e.g., siloxane); and any alkoxy or group, —OCₓH_{y}, where x=0-20, y=1-42. In certain embodiments, A is methylammonium (MA), (CH₃NH₃+). In certain embodiments, A is methylammonium. In certain embodiments, A is tetramethylammonium (TMA), ((CH₃)₄N⁺). In certain embodiments, A is butylammonium, which may be represented by (CH₃(CH₂)₃NH₃⁻) for n-butylammonium, by ((CH₃)₃CNH₃⁺) for t-butylammonium, or by (CH₃)₂CHCH₂NH₃⁺) for iso-butylammonium. In certain embodiments, A is phenylethylammonium (PEA′), which may be represented by C₆H₅(CH₂)₂NH₃ or by C₆H₅CH(CH₃)NH₃. In certain embodiments, A comprises phenylammonium, C₆H₅NH₃⁺. In certain embodiments, A is an ammonium cation selected from the group consisting of methylammonium (MA), tetramethylammonium (TMA), butylammonium (BAH), phenethylammonium (PEA), and phenylammonium (PHA), or a combination thereof.

In certain embodiments of the perovskite film, A may comprise a formamidinium, an organic cation of the general formula [R₂NCHNR₂]⁺ where the R groups can be the same or different groups. Suitable R groups include, but are not limited to: hydrogen, methyl, ethyl, propyl, butyl, pentyl or an isomer thereof; any alkane, alkene, or alkyne CₓH_{y}, where x=1-20, y=1-42, cyclic, branched or straight-chain; alkyl halides, CₓH_{y}X_{z}, x=1-20, y=0-42, z=1-42, X=F, Cl, Br, or I; any aromatic group (e.g., phenyl, alkylphenyl, alkoxyphenyl, pyridine, naphthalene); cyclic complexes where at least one nitrogen is contained within the ring (e.g., imidazole, benzimidazole, dihydropyrimidine, (azolidinylidenemethyl) pyrrolidine, triazole); any sulfur-containing group (e.g., sulfoxide, thiol, alkyl sulfide); any nitrogen-containing group (nitroxide, amine); any phosphorous containing group (phosphate); any boron-containing group (e.g., boronic acid); any organic acid (acetic acid, propanoic acid) and ester or amide derivatives thereof; any amino acid (e.g., glycine, cysteine, proline, glutamic acid, arginine, serine, histidine, 5-ammoniumvaleric acid) including alpha, beta, gamma, and greater derivatives; any silicon containing group (e.g., siloxane); and any alkoxy or group, —OCₓH_{y}, where x=0-20, y=1-42. In certain embodiments A is a formamidinium ion represented by (H₂N═CH—NH₂).

In certain embodiments of the perovskite film, A may comprise a guanidinium, an organic cation of the general formula [(R₂N)₂C═NR₂]⁺ where the R groups can be the same or different groups. Suitable R groups include, but are not limited to: hydrogen, methyl, ethyl, propyl, butyl, pentyl group or isomer thereof; any alkane, alkene, or alkyne CₓH_{y}, where x=1-20, y=1-42, cyclic, branched or straight-chain; alkyl halides, CₓH_{y}X_{z}, x=1-20, y=0-42, z=1-42, X=F, Cl, Br, or I; any aromatic group (e.g., phenyl, alkylphenyl, alkoxyphenyl, pyridine, naphthalene); cyclic complexes where at least one nitrogen is contained within the ring (e.g., octahydropyrimido[1,2-a]pyrimidine, pyrimido[1,2-a]pyrimidine, hexahydroimidazo[1,2-a] imidazole, hexahydropyrimidin-2-imine); any sulfur-containing group (e.g., sulfoxide, thiol, alkyl sulfide); any nitrogen-containing group (nitroxide, amine); any phosphorous containing group (phosphate); any boron-containing group (e.g., boronic acid); any organic acid (acetic acid, propanoic acid) and ester or amide derivatives thereof; any amino acid (e.g., glycine, cysteine, proline, glutamic acid, arginine, serine, histidine, 5-ammoniumvaleric acid) including alpha, beta, gamma, and greater derivatives; any silicon containing group (e.g., siloxane); and any alkoxy or group, —OCₓH_{y}, where x=0-20, y=1-42. In certain embodiments, A is a guanidinium ion of the type (H₂N═C═(NH₂)₂⁺).

In certain embodiments of the perovskite film, A may comprise an alkali metal cation, such as Li+, Na+, K+, Rb+, or Cs+.

In certain embodiments of the perovskite film, A is a cation selected from the group consisting of methylammonium (MA), tetramethylammonium (TMA), formamidinium (FA), caesium (Cs), rubidium (Rb), potassium (K), sodium (Na), butylammonium (BAH), phenethylammonium (PEA), phenylammonium (PHA), and guanidinium (GU), or a combination thereof.

In certain embodiments of the perovskite film, A comprises X_{c}Y_{(1-c)} wherein X and Y are a combination of two cations selected from the group consisting of methylammonium (MA), tetra-methylammonium (TMA), formamidinium (FA), caesium (Cs), rubidium (Rb), potassium (K), sodium (Na), butylammonium (BA), phenethylammonium (PEA), phenylammonium (PA), and guanidinium (GA). In certain embodiments of the perovskite film, A comprises a combination of two cations wherein “c” is the molar ratio of X:Y and is between 0.01 and 1.0. In certain embodiments of the perovskite film, A comprises FA and another cation selected from the group above. In certain embodiments, A comprises FA and Cs. In certain embodiments of the perovskite film, c is 0.01, 0.02, 0.03, 0.04, 0.05, 0.10, 0.15, 0.20, 0.25, 0.30, 0.35, 0.40, 0.41, 0.42, 0.43, 0.44, 0.45, 0.46, 0.47, 0.48, 0.49, 0.50, 0.55, 0.60, 0.65, 0.70, 0.75, 0.80, 0.85, 0.90, 0.95, or 1. In certain embodiments of the perovskite film, c is between 0.01 and 0.05, 0.01 and 0.03, 0.01 and 0.15, 0.02 and 0.10, 0.01 and 0.5, 0.01 and 0.75, 0.3 and 0.6, 0.2 and 0.7, 0.1 and 0.8, 0.3 and 0.5, 0.4 and 0.9, or 0.4 and 0.6.

In certain embodiments of the perovskite film, A is selected from the group consisting of Cs, FA, and MA, or a combination thereof. In certain embodiments, A is a combination of FA and Cs.

In certain embodiments, the perovskite crystal structure composition may be doped (e.g., by partial substitution of the cation A and/or the metal B) with a doping element, which may be, for example, an alkali metal (e.g., Li⁺, Na⁺, K⁺, Rb⁺, or Cs⁺), an alkaline earth metal (e.g., Mg⁺², Ca⁺², Sr⁺², Ba⁺²) or other divalent metal, such as provided below for B, but different from B (e.g., Sn⁺², Pb⁺², Zn⁺², Cd⁺², Ge⁺², Ni⁺², Pt⁺², Pd⁺², Hg⁺², Si⁺², Ti⁺²), or a Group 15 element, such as Sb, Bi, As, or P, or other metals, such as silver, copper, gallium, indium, thallium, molybdenum, or gold, typically in an amount of up to or less than about 1, 5, 10, 20, 25, 30, 35, 40, 45, 50, 55, 60, 65, 70, 75, 80, 85, 90, 95, 99, or 100 mol % of A or B. A may comprise a mixture of cations. B may comprise a mixture of cations.

The variable B comprises at least one divalent (B 2) metal atom. The divalent metal (B) can be, for example, one or more divalent elements from Group 14 of the Periodic Table (e.g., divalent lead, tin, or germanium), one or more divalent transition metal elements from Groups 3-12 of the Periodic Table (e.g., divalent titanium, vanadium, chromium, manganese, iron, cobalt, nickel, copper, zinc, palladium, platinum, and cadmium), and/or one or more divalent alkaline earth elements (e.g., divalent magnesium, calcium, strontium, and barium). In certain embodiments, the at least one divalent metal is selected from the group consisting of lead, tin, cadmium, germanium, zinc, nickel, platinum, palladium, mercury, titanium, silicon, and a combination thereof. In certain embodiments, B is lead.

In certain embodiments of the perovskite film, B comprises D_{g}E_{(1-g)}, wherein D and E are a combination of one or more divalent elements from Group 14 of the Periodic Table (e.g., divalent lead, tin, or germanium), one or more divalent transition metal elements from Groups 3-12 of the Periodic Table (e.g., divalent titanium, vanadium, chromium, manganese, iron, cobalt, nickel, copper, zinc, palladium, platinum, and cadmium), and/or one or more divalent alkaline earth elements (e.g., divalent magnesium, calcium, strontium, and barium). In certain embodiments of the perovskite film, B comprises a combination of two cations wherein “g” is the molar ratio of D:E and is between 0.01 and 1.0. In certain embodiments of the perovskite film, g is 0.01, 0.02, 0.03, 0.04, 0.05, 0.10, 0.15, 0.20, 0.25, 0.30, 0.35, 0.40, 0.41, 0.42, 0.43, 0.44, 0.45, 0.46, 0.47, 0.48, 0.49, 0.50, 0.55, 0.60, 0.65, 0.70, 0.75, 0.80, 0.85, 0.90, 0.95, or 1. In certain embodiments of the perovskite film, g is between 0.01 and 0.05, 0.01 and 0.03, 0.01 and 0.15, 0.02 and 0.10, 0.01 and 0.5, 0.01 and 0.75, 0.3 and 0.6, 0.2 and 0.7, 0.1 and 0.8, 0.3 and 0.5, 0.4 and 0.9, or 0.4 and 0.6. In certain embodiments, the at least one divalent metal is selected from the group consisting of lead, tin, cadmium, germanium, zinc, nickel, platinum, palladium, mercury, titanium, silicon, and a combination thereof. In certain embodiments of the perovskite film, B comprises Pb and another cation selected from the group above. In certain embodiments, B comprises Pb and Sn.

The variable X is independently selected from one or a combination of halide atoms, wherein the halide atom (X) may be, for example, fluoride (F⁻), chloride (Cl⁻), bromide (Br⁻), and/or iodide (I⁻). In certain embodiments, the at least one halide is selected from the group consisting of I, Br, and a combination thereof. In certain embodiments, X is selected from the group consisting of SCN⁻, BF₄⁻, F⁻, Cl⁻, Br⁻, I⁻, and a combination thereof.

In certain embodiments, the crystalline perovskite composition of Formula (I) is selected from the group consisting of cesium lead iodide (CsPbI₃), methylammonium tin iodide (CH₃NH₃SnI₃), cesium tin iodide (CsSnI₃), methylammonium lead iodide (CH₃NH₃PbI₃), cesium lead bromide (CsPbBr₃), methylammonium tin bromide (CH₃NH₃SnBr₃), cesium tin bromide (CsSnBr₃), methylammonium lead bromide, (CH₃NH₃PbBr₃), formamidinium tin bromide (CHNH₂NH₂SnBr₃), formamidinium lead bromide (CHNH₂NH₂PbBr₃), formamidinium tin iodide (CHNH₂NH₂SnI₃), formamidinium lead iodide (CHNH₂NH₂PbI₃), cesium formamidinium lead iodide (Cs_{0.1}FA_{0.9}PbI₃), cesium formamidinium methylammonium lead iodide (Cs_{0.05}FA_{0.70}MA_{0.25}PbI₃), cesium formamidinium lead tin iodide (Cs_{0.2}FA_{0.8}Pb_{0.5}Sn_{0.5}I3), cesium formamidinium lead iodide bromide (Cs_{0.2}FA_{0.8}Pb(I_{0.6}Br_{0.4})₃), and cesium methylammonium lead iodide bromide (Cs_{0.1}MA_{0.9}Pb(I_{0.9}Br_{0.1})₃). In certain embodiments, the crystalline perovskite composition of Formula (I) is selected from the group consisting of CsPbI₃, MAPbI₃, FAPbI₃, MA_{0.7}FA_{0.3}PBI₃, FA_{0.7}MA_{0.3}PbI₃, Cs_{0.08}FA_{0.92}PbI₃, Cs_{0.05}FA_{0.70}MA_{0.25}PbI₃, and Cs_{0.2}FA_{0.8}Pb_{0.5}Sn_{0.5}I₃. In a preferred embodiment, the crystalline perovskite composition of Formula (I) is methylammonium formamidinium lead iodide (MA_{0.7}FA_{0.3}PBI₃) or (FA_{0.7}MA_{0.3}PbI₃). In another preferred embodiment, the crystalline perovskite composition of Formula (I) is cesium formamidinium lead iodide (Cs_{0.05}FA_{0.92}PbI₃). In yet another preferred embodiment, the polycrystalline perovskite composition of Formula (I) is methylammonium lead iodide (MAPbI₃).

In embodiments, the subject matter described herein is directed to polycrystalline perovskite films characterized by a chemical formula comprising at least two chemical species, A and B, each independently selected from the group consisting of Pb, Cs, Sn, Sb, Fe, Ge, Mn, Mo, Ta, Ag, Na, K, Ru, Bi, Cs, Mg, Ti, Mn, Mg, V, Ni, Cu, Cd, Hg, Ga, In, formamidinium (“FA”), methylammonium (“MA”), ethylammonium, propylammonium, butylammonium, amylammonium, hexylammonium, heptylammonium, octylammonium, oleylammonium, formamidinium, dodecylammonium, phenylethylammonium, benzylammonium, ethylenediammonium, tetramethylammonium, tetraethylammonium, tetrabutylammonium, hexadecyl trimethyl ammonium, and ethanediammonium, and at least one chemical species, X, selected from the group consisting of I, Br, Cl, F, COO, BF₃, and SCN. In certain embodiments, the chemical formula of the polycrystalline perovskite film is selected from the group consisting of ABX₃, A₂BX₄, A₂BB X₆, A₃B₂X₉, and A₂BX₆, wherein B and B′ can each independently be monovalent, divalent, trivalent, or tetravalent metal cations selected from the list consisting of Pb, Cs, Sn, Sb, Fe, Ge, Mn, Mo, Ta, Ag, Na, K, Ru, Bi, Cs, Mg, Ti, Mn, Mg, V, Ni, Cu, Cd, Hg, Ga, and In, or a combination thereof. In certain embodiments, the polycrystalline perovskite film comprises a double perovskite, for example, Cs₂AgBiX₆. In certain embodiments, the polycrystalline perovskite film comprises a low dimensional perovskite, for example, PEA₂PbX₄.

In certain embodiments of the perovskite film, the perovskite film has a thickness of about 300 nm to about 2000 nm. In certain embodiments, the perovskite film has a thickness of about 300 nm to about 1000 nm, about 300 nm to about 500 nm, about 400 nm to about 800 nm, about 500 nm to about 1500 nm, about 600 nm to about 1800 nm, about 300 nm to about 900 nm, about 1000 nm to about 1500 nm, about 1000 nm to about 2000 nm, about 400 nm to about 1100 nm, about 1200 nm to about 1500 nm, about 1300 nm to about 1800 nm, about 300 nm to about 400 nm, about 400 nm to about 500 nm, about 500 nm to about 600 nm, about 600 nm to about 700 nm, about 700 nm to about 800 nm, about 800 nm to about 900 nm, about 900 nm to about 1000 nm, about 1000 nm to about 1100 nm, about 1100 nm to about 1200 nm, about 1200 nm to about 1300 nm, about 1300 nm to about 1400 nm, about 1400 nm to about 1500 nm, about 1500 nm to about 1600 nm, about 1600 nm to about 1700 nm, about 1700 nm to about 1800 nm, about 1800 nm to about 1900 nm, or about 1900 nm to about 2000 nm.

In certain embodiments, the subject matter disclosed herein is directed to perovskite precursor solutions, comprising a composition of Formula I as described above and a solvent. In certain embodiments of the ink solution, the solvent is selected from the group consisting of dimethyl sulfoxide, dimethylformamide, dichloromethane, tetrahydrofuran, γ-butyrolactone, 2-methoxyethanol, N,N′-Dimethylpropyleneurea, N-methyl-2-pyrrol-idone, and acetonitrile, or a combination thereof. In certain embodiments, the solvent is selected from one or more of dimethyl sulfoxide, dimethylformamide, 2-methoxyethanol, acetonitrile, methanol, propanol, butanol, tetrahydrofuran, pyridine, alkylpyridine, pyrrolidine, chlorobenzene, dichlorobenzene, dichloromethane, 1-methoxypropan-2-ol, 2-methoxy-1-methylethyl acetate, 2-butoxyethanol, 2-butoxyethyl acetate, 2-(propyloxy) ethanol, ethyl 3-ethoxypropionate, glycol ethers, dimethylacetamide, acetone, N,N′-Dimethylpropyleneurea, and chloroform. In certain embodiments, the solvent is a mixed solvent. In certain embodiments, the mixed solvent comprises dimethyl sulfoxide (DMSO) and dimethylformamide (DMF). In certain embodiments, the ratio of DMSO:DMF is 1:3.

b. Compositions of Formula (II)

Described herein are organosulfide compounds of Formula (II) used as passivating materials disposed on the polycrystalline perovskite film, said perovskite film comprising one or more of the compositions of Formula (I) described above.

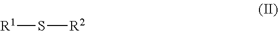

In embodiments described herein, R¹ and R² are each independently selected from the group consisting of alkyl, cycloalkyl, and aryl. In certain embodiments, said alkyl is (C₁-C₆) alkyl and is selected from the group consisting of methyl, ethyl, propyl, isopropyl, butyl, isobutyl, tert-butyl, sec-butyl, pentyl and hexyl, or a combination thereof. In certain embodiments, said cycloalkyl is selected from the group consisting of cyclopropyl, cyclobutyl, cyclopentyl, bicyclopentyl, cyclohexyl, cycloheptyl, spirocycloheptyl, and cyclooctane, or a combination thereof. In certain embodiments, said aryl is selected from the group consisting of phenyl, benzyl, naphthalyl, tolyl, and xylyl, or a combination thereof.

In embodiments described herein, R¹ and R² are identical. In certain embodiments, R¹ and R² are different. In certain embodiments, R¹ and R² are both (C₁-C₆) alkyl. In certain embodiments, R¹ is (C₁-C₆)alkyl and R² is cycloalkyl or aryl. In certain embodiments, R¹ and R² are both cycloalkyl. In certain embodiments, R¹ is cycloalkyl and R² is (C₁-C₆) alkyl or aryl. In certain embodiments, R¹ and R² are both aryl. In certain embodiments, R¹ is aryl and R² is (C₁-C₆) alkyl or cycloalkyl. In certain embodiments, R¹ and R² are both phenyl.

In embodiments described herein, said organosulfide material is a compound selected from the group consisting of ethyl propyl sulfide, butyl methyl sulfide, dipropyl sulfide, butyl ethyl sulfide, methyl pentyl sulfide, dibutyl sulfide, ethyl 1-octyl sulfide, dipentyl sulfide, dihexyl sulfide, diheptyl sulfide, dioctyl sulfide, ethyl isopropyl sulfide, diallyl sulfide, diisopropyl sulfide, tert-butyl ethyl sulfide, methyl tert-butyl sulfide, isopropyl propyl sulfide, methyl phenyl sulfide, phenyl vinyl sulfide, ethyl phenyl sulfide, diphenyl sulfide, di-tert-butyl sulfide, di-sec-butyl sulfide, diisobutyl sulfide, allyl phenyl sulfide, di-1-napthyl sulfide and dibenzyl sulfide. In certain embodiments, said organosulfide material is diphenyl sulfide.

In embodiments described herein, the passivating layer comprising an organosulfide material is disposed on at least about 80% of perovskite film. In certain embodiments, the passivating layer is disposed on at least about 80%, 81%, 82%, 83%, 84%, 85%, 86%, 87%, 88%, 89%, 90%, 91%, 92%, 93%, 94%, 95%, 96%, 97%, 98%, 99%, or 100% of the perovskite film. In certain embodiments, the passivating layer is disposed on about 99% or 100% of the perovskite film.

In embodiments, the subject matter described herein is directed to precursor passivating solutions, comprising an organosulfide compound of Formula (II) as described above and a solvent. In embodiments described herein, the solvent is selected from the group consisting of dimethyl sulfoxide, dimethylformamide, dichloromethane, tetrahydrofuran, γ-butyrolactone, 2-methoxyethanol, N,N′-Dimethylpropyleneurea, N-methyl-2-pyrrol-idone, and acetonitrile, or a combination thereof. In certain embodiments, the solvent is selected from one or more of dimethyl sulfoxide, dimethylformamide, 2-methoxyethanol, acetonitrile, methanol, propanol, isopropanol, butanol, tetrahydrofuran, pyridine, alkylpyridine, pyrrolidine, chlorobenzene, dichlorobenzene, dichloromethane, 1-methoxypropan-2-ol, 2-methoxy-1-methylethyl acetate, 2-butoxyethanol, 2-butoxyethyl acetate, 2-(propyloxy) ethanol, ethyl 3-ethoxypropionate, glycol ethers, dimethylacetamide, acetone, N,N′-Dimethylpropyleneurea, and chloroform. In certain embodiments, the solvent is isopropanol.

### IV. Methods of Preparing the Multilayer Perovskite Composite

In embodiments, the subject matter described herein is directed to a method for preparing a multilayer perovskite composite using the precursor solutions disclosed herein, comprising:
disposing a precursor passivating solution comprising an organosulfide material and a solvent onto a surface of the polycrystalline perovskite film using a fast-coating process such that a passivating layer forms on said surface of the polycrystalline perovskite film;
   wherein said passivating layer comprises an organosulfide material.

In certain embodiments, the fast-coating process is selected from the group consisting of spin coating, blade coating, slot die coating, shear coating, gravure coating, brush coating, syringe coating, and screen printing.

In certain embodiments of the above method, the fast-coating process is spin coating. In certain embodiments, a device is used in the fast-coating process for contacting the precursor solution onto the substrate. The spin coating process is a four-step process: deposition, spin up, spin off, and evaporation. In the first step, the precursor solution is deposited on a turntable followed by the spin up and spin off steps in sequence while the evaporation stage occurs throughout the process. High spinning speeds result in the thinning of the applied precursor solution on the turntable. The rapid rotation facilitates uniform evaporation of the high volatile components and solvent. In certain embodiments, the spin coating process proceeds at rotation speeds between 1000 and 600 rpm.

In certain embodiments of the above method, the fast-coating process is blade coating. In certain embodiments, a device is used in the fast-coating process for contacting the precursor solution onto the substrate. In the blade coating process, a “blade coater” may be used. As used herein, “blade coater” is synonymous with “doctor blade.” In certain embodiments, doctor blade coating techniques are used to facilitate formation of the perovskite film during the fabrication process.

Utilizing a fast coating process is advantageous because of increased scalability for perovskite device roll-to-roll production, simplicity, and cost effectiveness. Furthermore, fast coating processes also provide advantages due to high-throughput deposition, high material usage, and application onto flexible substrates. In particular, perovskite films and devices fabricated using a fast coating process, such as blade coating, can have advantageously long carrier diffusion lengths (e.g., up to 3 μm thick) due to the dramatically higher carrier mobility in the blade-coated films. Such doctor-blade deposition can be utilized for large area perovskite cells fabricated with high volume roll-to-roll production.

In certain embodiments, the method for producing a polycrystalline perovskite film using the fast coating process can take place at a temperature between about 25° C. to about 250° C. In certain embodiments, the process takes place at about room temperature (about 25° C.).

In certain embodiments of the fast coating process, the substrate is moving and the device is stationary. In certain embodiments, the device is a doctor blade. In certain aspects, the substrate is moving at a rate of about 2 mm/s relative to the device. In certain aspects, the substrate is moving at a rate of about 20 mm/s relative to the device. In certain aspects, the substrate is moving at a rate of about 40 mm/s relative to the device. In certain aspects, the substrate is moving at a rate of about 99 mm/s relative to the device. In certain aspects, the substrate is stationary and the device moves relative to the substrate. In certain aspects, the device is moving at a rate of about 2 mm/s relative to the substrate. In certain aspects, the device is moving at a rate of about 20 mm/s relative to the substrate. In certain aspects, the device is moving at a rate of about 40 mm/s relative to the substrate. In certain aspects, the device is moving at a rate of about 99 mm/s relative to the substrate.

In certain embodiments, the fast coating process described herein takes place at about 2 to about 15,000 mm/s. In certain embodiments, the fast coating process described herein takes place at about 2 to about 10,000 mm/s. In certain embodiments, the fast coating process described herein takes place at about 2 to about 99 mm/s. In certain embodiments, the fast coating process takes place at least or at about 2 mm/s, 15 mm/s, 20 mm/s, 40 mm/s, 60 mm/s, 80 mm/s, 99 mm/s, 150 mm/s, 275 mm/s, 500 mm/s, 700 mm/s, 800 mm/s, 900 mm/s, 1000 mm/s, 2000 mm/s, 3000 mm/s, 4000 mm/s, 5000 mm/s, 6000 mm/s, 7000 mm/s, 8000 mm/s, 9000 mm/s, or about 10,000 mm/s.

In certain embodiments, the distance between the devices used in the fast coating process for contacting the precursor perovskite solution onto the substrate is between about 10 μm and 1 cm. In certain embodiments, the distance between the device and the substrate is between about 150 and about 350 μm. In certain embodiments, the distance between the device and the substrate is between about 200 and about 300 μm. In certain embodiments, the distance between the device and the substrate is about 200 μm, 225 μm, about 250 μm, about 275 μm, or about 300 μm. In a preferred embodiment, the distance between the device and the substrate is about 100 μm.

In certain embodiments, the methods described herein to produce polycrystalline perovskite films further comprise knife-assisted drying. Knife drying comprises applying a high velocity, low pressure gas to the precursor perovskite solution to form a perovskite film on the substrate. An advantage of knife drying in the polycrystalline perovskite film production process is that it helps produce uniform and smooth films. As used herein, an “air knife,” “N2 knife,” or “air doctor” may be used to describe the device that performs knife-assisted drying in the perovskite film production process. The knife may have a gas manifold with a plurality of nozzles that direct a high velocity stream of air or other gas at the perovskite ink on the substrate. The gas used in the knife-assisted drying process may be air, nitrogen, argon, helium, oxygen, neon, hydrogen, and a combination thereof.

In certain embodiments, the knife-assisted drying takes place at a temperature of about 25° C. to about 250° C. In certain embodiments, the knife-assisted drying takes place at room temperature (about 25° C.). In certain embodiments, the knife-assisted drying takes place at a temperature of about 50° C. to about 100° C.

In certain embodiments, the knife-assisted drying takes place at a pressure in a range of about 0 to 500 psi. In certain embodiments, the knife-assisted drying takes place at a pressure in a range of about 5 to 400 psi, about 20 to 300 psi, about 50 to 200 psi, about 100 to 150 psi, about 5 to 25 psi, about 5 to 20 psi, about 10 to 20 psi, about 10 to 19 psi, about 12 to 18 psi, about 12-16 psi, or about 13-16 psi. In certain embodiments, the knife-assisted drying takes place at about 14 psi, about 15, psi, about 16 psi, at about 17 psi, at about 18 psi, or at about 19 psi.

In certain embodiments, the knife is angled against the device used in the fast coating process and the substrate to create a unidirectional air flow over the as-coated film for enhanced blowing uniformity. In certain embodiments, the knife is angled 0°, 5°, 10°, 15°, 20°, 25°, 30°, 35°, 40°, 45°, 50°, 55°, 60°, 65°, 70°, 75°, 80°, 90°, 100°, 120°, 150°, 155°, 170°, or 180° against the device or the substrate.

In certain embodiments, after fast coating, the film created from the precursor perovskite solution (while on the substrate) may undergo annealing. The film is annealed at a temperature of at least or above 30° C. In certain embodiments, annealing employs a temperature of about, at least, above, up to, or less than 40° C., 50° C., 60° C., 70° C., 80° C., 90° C., 100° C., 110° C., 120° C., 130° C., 140° C., 150° C., 160° C., 170° C., 180° C., 190° C., or 200° C., or a temperature within a range bounded by any two of the foregoing values. In various embodiments, annealing may take place in a range of, for example, 30-200° C., 50-150° C., 30-180° C., 30-150° C., 30-140° C., 30-130° C., 30-120° C., 30-110° C., or 30-100° C. In a preferred embodiment, the annealing temperature is 70° C.

Annealing may take place for a period of time, for example, in a range of about 0 seconds to 400 minutes, about 5 seconds to 30 seconds, about 5 minutes to about 10 minutes, about 10 minutes to 20 minutes, or about 20 minutes to 30 minutes. Annealing can take place for a period of time, for example, of at least 5 seconds, 10 seconds, 20 seconds, 30 seconds, 1, minute, 5 minutes, 10 minutes, 20 minutes, 30 minutes, 60 minutes, 90 minutes, 120 minutes, 180 minutes, 240 minutes, or 360 minutes.

In certain embodiments of the above method, the multilayer perovskite composite prepared has an overall thickness of about 300 nm to about 2000 nm. In certain embodiments, the multilayer perovskite composite prepared has a thickness of about 300 nm to about 1000 nm, about 300 nm to about 500 nm, about 400 nm to about 800 nm, about 500 nm to about 1500 nm, about 600 nm to about 1800 nm, about 300 nm to about 900 nm, about 1000 nm to about 1500 nm, about 1000 nm to about 2000 nm, about 400 nm to about 1100 nm, about 1200 nm to about 1500 nm, about 1300 nm to about 1800 nm, about 300 nm to about 400 nm, about 400 nm to about 500 nm, about 500 nm to about 600 nm, about 600 nm to about 700 nm, about 700 nm to about 800 nm, about 800 nm to about 900 nm, about 900 nm to about 1000 nm, about 1000 nm to about 1100 nm, about 1100 nm to about 1200 nm, about 1200 nm to about 1300 nm, about 1300 nm to about 1400 nm, about 1400 nm to about 1500 nm, about 1500 nm to about 1600 nm, about 1600 nm to about 1700 nm, about 1700 nm to about 1800 nm, about 1800 nm to about 1900 nm, or about 1900 nm to about 2000 nm. In certain embodiments of the above method, the multilayer perovskite composite prepared has a thickness of about 800 nm to about 1500 nm.

### V. Devices

In embodiments, the subject matter described herein is directed to electronic devices having the multilayer perovskite composite, according to embodiments disclosed herein, as an active layer. In certain embodiments, the electronic device is a perovskite photon counting detector.

In embodiments, the perovskite photon counting detector comprises: one or more transparent conductive oxide layers; one or more conductive electrode layers; and an active layer comprising the multilayer perovskite composite described herein. In certain embodiments, the perovskite photon counting detector further comprises one or more hole transport layers; one or more buffer layers; and one or more electron transport layers. In certain embodiments, the active layer comprises a multilayer perovskite composite, said multilayer perovskite composite comprising a polycrystalline perovskite film comprising a composition of Formula (I) and a passivating layer disposed on at least some of said polycrystalline perovskite film, wherein the passivating layer comprises an organosulfide material, according to embodiments disclosed herein. In an embodiment, the surface of the perovskite film is an interface between the perovskite film and the passivating layer. In an embodiment, the one or more conductive oxide layers and the one or more conductive electrode layers are in electronic communication with the multilayer perovskite composite of the active layer. In an embodiment, the active layer comprising the multilayer perovskite composite is positioned between the one or more conductive oxide layers and one or more conductive electrode layers. In an embodiment, the perovskite photon counting detector further comprises a hole transport layer in direct electronic communication with the multilayer perovskite composite of the active layer. In an embodiment, the perovskite photon counting detector further comprises an electron transport layer in direct electronic communication with the multilayer perovskite composite of the active layer. The terms electron transport layer and hole transport layer are known terms in the field of photoactive devices, such as solar cells and light emitting diodes.

In certain embodiments, the perovskite photon counting detector comprises:
a transparent conductive oxide layer;
a hole transport layer;
an active layer comprising the multilayer perovskite composite according to embodiments disclosed herein;
an electron transport layer;
a buffer layer; and
a conductive electrode layer.

In embodiments, the subject matter described herein is directed to the perovskite photon counting detector wherein:
the hole transport layer is disposed on the transparent conductive oxide layer;
the polycrystalline perovskite film of the multilayer perovskite composite is disposed on the hole transport layer;
the passivating layer of the multilayer perovskite composite is disposed on the polycrystalline perovskite film of the multilayer perovskite composite;
the electron transport layer is disposed on the passivating layer of the multilayer perovskite composite;
the buffer layer is disposed on the electron transport layer; and
the conductive electrode layer is disposed on the buffer layer.

In certain embodiments, the transparent conductive oxide layer and the conductive electrode layer comprise the anode and cathode (or vice versa) in the perovskite photon counting detector. In certain embodiments, the cathode and anode each comprise at least one of lithium, sodium, potassium, rubidium, caesium, francium, beryllium, magnesium, calcium, strontium, barium, radium, boron, aluminum, gallium, indium, thallium, tin, lead, flerovium, bismuth, antimony, tellurium, polonium, scandium, titanium, vanadium, chromium, manganese, iron, cobalt, nickel, copper, zinc, yttrium, zirconium, niobium, molybdenum, technetium, ruthenium, rhodium, palladium, silver, cadmium, hafnium, tantalum, tungsten, rhenium, osmium, iridium, platinum, gold, mercury, rutherfordium, dubnium, seaborgium, bohrium, hassium, copernicium, samarium, neodymium, ytterbium, an alkali metal fluoride, an alkaline-earth metal fluoride, an alkali metal chloride, an alkaline-earth metal chloride, an alkali metal oxide, an alkaline-earth metal oxide, a metal carbonate, a metal acetate, carbon nanowire, carbon nanosheet, carbon nanorod, carbon nanotube, graphite, indium tin oxide (ITO), fluorine-doped tin oxide (FTO), aluminum doped zinc oxide (AZO), antimony-tin mixed oxide (ATO), network of metal/alloy nanowire, or a combination of two or more of the above materials. In an embodiment, the positive electrode is a cathode. In an embodiment, the negative electrode is an anode. In an embodiment, the negative electrode is a terminal for connection to an external circuit. In an embodiment, the positive electrode is a terminal for connection to an external circuit.

In certain embodiments, the transparent conductive oxide layer is selected from the group consisting of ITO, FTO, ZITO, and AZO. In certain embodiments, the metal electrode is selected from the group consisting of Al, Au, Cu, Cr, Ca, Mg, Bi, Ag, and Ti.

In certain embodiments, the perovskite photon counting detector described herein contains two transparent conductive oxide layers, each independently selected from the group consisting of ITO, FTO, ZITO, and AZO.

In certain embodiments, the hole transport layer comprises at least one of poly(3,4-ethylene dioxithiophene) (PEDOT—acidic or neutral), poly(3,4-ethylene dioxithiophene) (PEDOT) doped with poly(styrene sulfon icacid) (PSS) [PEDOT:PSS], Spiro-OMeTAD, pm-spiro-OMeTAD, po-spiro-OMeTAD, dopants in spiro-OMeTAD, 4,4′-biskptrichlorosilylpropylphenyl)phenylaminoThiphenyl (TPD-Si2), (2-(3,6-Dimethoxy-9H-carbazol-9-yl)ethyl)phosphonic acid (MeO-2PACz), poly(3-hexyl-2,5-thienylene vinylene) (P3HTV), C60, carbon, carbon nanotube, graphene quantum dot, graphene oxide, copper phthalocyanine (CuPc), Polythiophene, poly(3,4-(1hydroxymethyl)ethylenedioxythiophene (PHMEDOT), n-dodecylbenzenesulfonic acid/hydrochloric acid doped poly(aniline) nanotubes (a-PANIN)s, poly(styrene sulfonic acid)-graft-poly(aniline) (PSSA-g-PANI), poly(9. 9-dioctylfluorene)-co-N-(4-(1-methylpropyl)phenyl) diphenylamine (PFT), 4,4′-bis(p-trichlorosilylpropylphenyl)phenylaminobiphenyl (TSPP), 5,5′-bis(p-trichlorosilylpropylphenyl)phenylamino-2,20 bithiophene (TSPT), N-propyltriethoxysilane, 3,3,3-trifluo ropropyltrichlorosilane or 3-aminopropyltriethoxysilane, Poly(bis(4-phenyl) (2,4,6-trimethylphenyl)amine) (PTAA), (Poly [[(2,4-dimethylphenyl)imino]-1,4-phenylene (9,9-dioctyl-9H-fluorene-2,7-diyl)-1,4phenylene], (PF8-TAA)), (Poly [[(2,4-dimethylphenyl)imino]-1,4-phenylene (6,12-dihydro-6,6,12,12tetraoctylindeno[1,2-b]fluorene-2,8-diyl)-1,4-phenylene]) (PIF8-TAA), poly [[4,8-bis[(2-ethylhexyl)oxy]benzo[1,2-b: 4,5-b]dithiophene-2,6-diyl][3-fluoro-2-[(2-ethylhexyl) carbonyl]thieno[3,4-b]thiophenediyl]] (PTB7), poly [N-90-heptadecanyl-2,7-carbazole-alt-5,5-(40,70-di-2-thienyl-20,10,30-benzothiadiazole)] (PCDTBT), Poly [2,5-bis(2-decyldodecyl) pyrrolo[3,4-c]pyrrole-1,4 (2H,5H)-dione-(E)-1,2-di(2,20-bithiophen-5-yl) ethene] (PDPPDBTE), 4,8-dithien-2-yl-benzo[1,2-d; 4,5-d ‘]bistriazole-alt-benzo[1,2-b: 4,5b’]dithiophenes (pBBTa-BDTs), pBBTa-BDT1, pBBTa-BDT2 polymers, poly(3-hexylthiophene) (P3HT), poly(4,4′-bis(N-carbazolyl)-1,1′-biphenyl) (PPN), triarylamine (TAA) and/or thiophene moieties, Paracyclophane, Triptycene, and Bimesitylene, Thiophene and Furan-based hole transport materials, Dendrimer-like and star-type hole transport materials, VO, VOX, MoC, WO, ReO, NiOₓ, AgOₓ, CuO, CuzO, V₂O₅, CuI, CuS, CuInS₂, colloidal quantum dots, lead sulphide (PbS), CuSCN, Cu₂ZnSnS₄, Au nanoparticles and their derivatives. Thiophene derivatives, Triptycene derivatives, Triazine derivatives, Porphyrin derivatives, Triphenylamine derivatives, Tetrathiafulvalene derivatives, Carbazole derivatives and Phthalocyanine derivatives. As used herein, when a material is referred to a “derivate” or as “derivatives,” such as Triphenylamine derivatives, the material contains Triphenylamine in its backbone structure. In certain embodiments, the hole transport layer is selected from the group consisting of PEDOT, PTAA, Spiro-OMeTAD, PEDOT:PSS, NiO, MoO₃, MeO-2PACz, V₂O₅, Poly-TPD, EH44, P3HT, and a combination thereof. In embodiments described herein, the hole transport layer comprises poly(bis(4-phenyl)(2,4,6-trimethylphenyl)amine) (PTAA).

In certain embodiments, the electron transport layer comprises at least one of LiF, CsP, LiCoO, CsCO, TiO_{X}, TiO, nanorods (NRs), ZnO, ZnO nanorods (NRs), ZnO nanoparticles (NPs), ZnO, Al—O, CaO, bathocuproine (BCP), copper phthalocyanine (CuPc), pentacene, pyronin B, pentadecafluorooctyl phenyl-C60-butyrate (F-PCBM), C60, C60/LiF, ZnO NRS/PCBM, ZnO/cross-linked fullerene derivative (C-PCBSD), single walled carbon nanotubes (SWCNT), poly(ethylene glycol) (PEG), poly(dimethylsi loxane-block-methyl methacrylate) (PDMS-b-PMMA), polar polyfluorene (PF-EP), polyfluorene bearing lateral amino groups (PFN), polyfluorene bearing quaternary ammonium groups in the side chains (WPF-oxy-F), polyfluorene bearing quaternary ammonium groups in the side chains (WPF-6-oxy-F), fluorene alternating and random copolymer bearing cationic groups in the alkyl side chains (PFNBr DBT15), fluorene alternating and random copolymer bearing cationic groups in the alkyl side chains (PFPNBr), poly (ethylene oxide) (PEO), and fullerene derivatives. In certain embodiments, the electron transport layer is selected from the group consisting of C60, BCP, TiO₂, SnO₂, PCBM, ICBA, ZnO, ZrAcac, LIF, TPBI, PFN, Nb₂O₅, and a combination thereof.

In any of the embodiments above, the perovskite photon counting detector can further comprise a buffer layer. In certain embodiments, the buffer layer is disposed between the electron transport layer and said conductive electrode layer. In certain embodiments, the buffer layer is selected from the group consisting of PDI, PDINO, PFN, PFN—Br, SnO₂, ZnO, ZrAcac, TiO₂, BCP, LiF, PPDIN6, and TPBi. In certain embodiments, the buffer layer is BCP. In certain embodiments, the buffer layer is SnO₂.

In certain embodiments the conductive electrode layer has a thickness of about 1 nm to about 1000 μm, about 100 nm to about 500 nm, about 1 μm to about 500 μm, about 250 μm to about 1000 μm, or about 250 nm to about 250 μm. In certain embodiments, the conductive electrode has a thickness of about 10 nm, 50 nm, 100 nm, 150 nm, 200 nm, 300 nm, 400 nm, 500 nm, 550 nm, 1 μm, 10 μm, 20 μm, 30 μm, 40 μm, 50 μm, 60 μm, 70 μm, 80 μm, 100 μm, 150 μm, 200 μm, 250 μm, 300 μm, 350 μm, 400 μm, 450 μm, 500 μm, 550 μm, 600 μm, 700 μm, 800 μm, 900 μm, or 100 μm.

In certain embodiments, the transparent conductive oxide layer has a thickness of about 1 nm to about 1000 μm, about 100 nm to about 500 nm, about 1 μm to about 500 μm, about 250 μm to about 1000 μm, or about 250 nm to about 250 μm. In certain embodiments, the transparent conductive layer has a thickness of about 10 nm, 50 nm, 100 nm, 150 nm, 200 nm, 300 nm, 400 nm, 500 nm, 550 nm, 1 μm, 10 μm, 20 μm, 30 μm, 40 μm, 50 μm, 60 μm, 70 μm, 80 μm, 100 μm, 150 μm, 200 μm, 250 μm, 300 μm, 350 μm, 400 μm, 450 μm, 500 μm, 550 μm, 600 μm, 700 μm, 800 μm, 900 μm, or 100 μm.

In certain embodiments, the hole transport layer and electron transport layer each individually has a thickness of about 0.1 nm to about 10 μm, about 0.5 nm to about 100 nm, about 10 nm to about 500 nm, about 300 nm to about 700 nm, about 100 nm to about 1 μm, about 1 μm to about 10 μm, or about 800 nm to about 5 μm. In certain embodiments, the hole transport layer and electron transport layer each individually has a thickness of about 0.1 nm, 0.5 nm, 1.0 nm, 2.0 nm, 5.0 nm, 10 nm, 20 nm, 30 nm, 40 nm, 50 nm, 60 nm, 70 nm, 80 nm, 90 nm, 100 nm, 150 nm, 200 nm, 250 nm, 300 nm, 350 nm, 400 nm, 450 nm, 500 nm, 550 nm, 600 nm, 650 nm, 700 nm, 750 nm, 800 nm, 850 nm, 900 nm, 950 nm, 1000 nm, 1 μm, 2 μm, 3 μm, 4 μm, 5μ, 6 μm, 7μ m, 8 μm, 9 μm, or 10 μm.

In certain embodiments, the active layer comprising the multilayer perovskite composite according to embodiments disclosed herein is a wide bandgap multilayer perovskite composite. The wide bandgap multilayer perovskite composite having a bandgap of about 1.21 eV to about 2.4 eV. In certain embodiments, the wide bandgap material has a bandgap of about 1.3 eV to 2.3 eV, 1.4 eV to 2.2 eV, 1.5 eV to 2.1 eV, 1.6 eV to 2.0 eV, or 1.7 eV to 1.9 eV. In certain embodiments, the wide bandgap multilayer perovskite composite has a bandgap of about 1.4 eV, 1.41 eV, 1.42 eV, 1.43 eV, 1.44 eV, 1.45 eV, 1.46 eV, 1.47 eV, 1.48 eV, 1.49 eV, 1.50 eV, 1.51 eV, 1.52 eV, 1.53 eV, 1.54 eV, 1.55 eV, 1.56 eV, 1.57 eV, 1.58 eV, 1.59 eV, 1.60 eV, 1.62 eV, 1.63 eV, 1.64 eV, 1.65 eV, 1.66 eV, 1.67 eV, 1.68 eV, 1.69 eV, or 1.70 eV. In certain embodiments, the wide bandgap multilayer perovskite composite has a bandgap of about 1.51 eV.

In embodiments, the subject matter described herein is directed to a photon counting device. The photon counting device, comprising:
a neutral density filter;
the perovskite photon counting detector according to the embodiments described herein.
a charge sensitive pre-amplifier;
a shaping amplifier; and
a multichannel analyzer.

In embodiments, the subject matter described herein is directed to a method of counting photons, comprising:
exposing the perovskite photon detector according to the embodiments disclosed herein to a number of incident photons as controlled by a neutral density filter;
wherein an output signal is generated the perovskite photon counting detector and is amplified by a charge sensitive preamplifier and a shaping amplifier; and
wherein the amplified signal is analyzed and reported as histograms of photon counts by a multichannel analyzer.

In certain embodiments, the perovskite photon counting detector according to the embodiments disclosed herein can count a minimal detectable photon number from about 200 photons to about 1000 photons.

In certain embodiments, the perovskite photon counting detector has an internal quantum efficiency (IQE) of at least 90% for photon numbers from 700 photons to >10⁸ photons.

In certain embodiments, the perovskite photon counting detector has an internal quantum efficiency (IQE) of at least 95% for photon numbers from 700 photons to >10⁸ photons.

### EXAMPLES

### Materials and Methods

### I. Materials

Chemicals in this work were used as received. PTAA (average Mn 7,000-10,000), PMMA (average Mn 120,000), dimethyl sulfoxide (DMSO), dimethylformamide (DMF), acetonitrile, toluene, diphenyl sulfide (DS), and isopropanol (IPA) were purchased from Sigma-Aldrich. MAI and FAI were purchased from GreatCell Solar. PbI₂ was purchased from Tokyo Chemical Industry CO., LTD.

### II. Device Fabrication

Patterned ITO glass substrates were cleaned with detergent, acetone, and IPA in sequence and then treated with UV-ozone for 15 min. A PTAA solution with a concentration of 2 mg/ml in toluene was spin-coated onto the ITO substrate at 4000 rounds per minute (rpm) for 30 s, and the as-prepared PTAA film was annealed at 100° C. for 10 min. For MAPbI₃ films deposited by the two-step process: a PMMA solution with a concentration of 0.5 mg/ml in acetonitrile was spin-coated on the PTAA layer at 5000 rpm for 30 s, and the as-prepared PMMA film was annealed at 100° C. for 10 min. PbI₂ and MAI were dissolved in DMF and IPA with concentrations of 630 mg/ml and 65 mg/ml respectively. The PbI₂ solution was spin-coated onto the PTAA layer at 3000 rpm for 30 s and then annealed at 100° C. for 10 min. The MAI solution was spin-coated on the PbI₂ film at 3000 rpm for 30 s. The perovskite was obtained by annealing the stacked layers at 100° C. for 90 min. For MAPbI₃ films deposited by the one-step process: PbI₂ and MAI were dissolved into DMF and DMSO (with a volume ratio of 9:1) with a concentration of 1.3 M to obtain the MAPbI₃ precursor solution. 50 μl MAPbI₃ solution was spin-coated on the PTAA layer at 2000 rpm for 3 s and then 4000 rpm for 19 s, and 130 μl toluene was added to film during the spin-coating. The as-formed film was then annealed at 100° C. for 10 min. For FA_{0.7}MA_{0.3}PbI₃ devices, the films were deposited by the method described in our previous work¹³. For diphenyl sulfide surface treatment, a 5 mg/ml diphenyl sulfide solution in IPA was spin-coated on the MAPbI₃ layer at 5000 rpm for 30 s, and then annealed at 100° C. for 10 min. Then 100 nm thick C₆₀, 6 nm thick BCP, and 180 nm Cu were sequentially deposited on the MAPbI₃ layer by thermal evaporation, and the device area was defined by the overlapping of Cu electrode and ITO. All devices in this study have an active area of 1×1 mm². The completed devices were encapsulated with cover glass sealed by an epoxy encapsulant (Devcon 14210).

### III. Photon Counting Performance Measurement

The incident light was from a picosecond laser diode head (Horiba DD-635L) with a wavelength of 630 nm, and the laser head was driven by a Horiba DD-C1 controller, which was triggered by a pulse signal with a repetition frequency of 5 kHz generated by an oscilloscope (Agilent DSO-X 3104A). The incident photon number to detectors was controlled by neutral density filters (Thorlabs), and can be calculated through

$${N}_{i ncident photon} = \frac{{P}_{l a s e r}}{{f}_{l a s e r}} \times 1 {0}^{- O D} \times \frac{λ}{h c} ,$$

where Pₗₐₛₑᵣ is laser initial power, fₗₐₛₑᵣ is pulse repetition frequency, OD is the optical density of the neutral density filters, and λ is the wavelength of the laser. The detector output pulse signal was sequentially amplified by a charge sensitive preamplifier that has a gain of 1.1 mV/fC (Kromek Ltd, ev-550/ev-5094) and a shaping amplifier that has a gain of 1000× and a shaping time of 6 μs (Ortec, 572A), then record by an MCA (Ortec, easy-MCA). The charge sensitive preamplifier was not used when a SiPM was used as the photodetector, since it has intrinsic gain. The SiPM is Mircrofj-60035-TSV from Onsemi with an active area of 6.07×6.07 mm². Perovskite PCDs were measured at zero bias. For temperature dependent DCR measurement, the device temperature was controlled by the Linkam microscope temperature stage (LTS420), and the DCR measurements were taken after holding the device at the set temperature for 15-20 min. Five DCR histograms were collected at each temperature to calculate the average DCR for activation energy fitting.

### IV. Device Characterization

The SEM images were taken on a FEI Helois 600 nanolab dual beam system. The 5 kV at low vacuum mode was applied for characterization. Photoluminescence and TRPL were conducted using a FluoTime 300 system from PicoQuant. The excitation wavelength was 485 nm. The laser power was 0.198 mW with a frequency of 20 MHz for PL measurement, and 0.216 μW with a frequency of 0.02 MHz for TRPL measurement. The XRD was characterized by Rigaku SmartLab. The I-V curves for shunting resistance determination were acquired by a Keithley 4200A-SCS in the dark. The tDOS of perovskite detectors were derived from the frequency-dependent capacitance (C-f), which was from the thermal admittance spectroscopy (TAS) measurement performed by an LCR meter (Agilent E4980A). For DLCP measurement, the DC bias scanned from 0 V to the open-circle voltage (e.g. 1.1 V) for the perovskite detectors. The DLCP method uses a series of variable 8V (for example, 20-200 mV) to measure the junction capacitance and acquire the capacitance contribution from the trap states by taking advantage of the information embedded in the higher-order terms. The capacitance measured at each 8V was recorded and fitted with a polynomial function C=C₀+C₁δV+C₂ (δV)²+ . . . to obtain C₀ and C₁. With the determination of C₀ and C₁, the total carrier density (N) that includes both free carrier density and trap density at the profiling distance X from the junction barrier is calculated by

$$N = - \frac{{C}_{0}^{3}}{2 q ε {A}^{2} {C}_{1}} ,$$

in which q is the elementary charge, ε is the dielectric constant, which is 31 for MAPbI₃, and A is the active area of the junction. The profiling distance from the junction barrier was calculated by

$$\frac{ε A}{{C}_{0}} ,$$

which was changed by tuning the DC bias. For each AC bias, an additional offset DC voltage was applied to keep the maximum forward bias constant. All tDOS and DLCP measurements were finished in dark conditions.

### V. Internal Quantum Efficiency Measurement

The reflectivity (R) at 630 nm was measured using Lambda 1050 UV-Vis spectrophotometer. And the internal quantum efficiency was calculated by

$$IQE = \frac{E Q E}{1 - R} .$$

Since the MCA has 2048 channels and is saturated by a 14.2 V input bias, the collected charge number was derived by

$${N}_{c h a r g e} = \frac{Channel number \times 14.2 \times {10}^{- 15}}{2048 \times 1.1 \times e}$$

for photon number below 2.41×10⁶, in which e is the elementary charge. For photon number above 7.63×10⁶, the collected charge number was derived from charge amplifier output amplitude (V_{charge amplifier} in mV) by

$${N}_{c h a r g e} = \frac{{V}_{charge amplfieir} \times 1 {0}^{- 15}}{1.1 \times e} .$$

The external quantum efficiency (EQE) was obtained by

$$EQE = \frac{{N}_{c h a r g e}}{{N}_{incident photon}} ,$$

where N_{incident photon} is the incident photon number.

### VI. Gamma-Ray Spectrum Measurement

The γ-ray sources employed here were 1 μCi ¹³⁷Cs 662 keV and 1 μCi ⁵⁷Co 122 keV. The detectors were coupled with the LaBr₃:Ce scintillator (dimensions of Φ10×14 mm³ from Kinheng Crystal Material (Shanghai) Co., ltd.) using a polydimethylsiloxane film as coupling layer. The detectors coupled with scintillator and the γ-ray source were put in an aluminum shied box. The perovskite detectors were measured at zero bias, and the SiPM was measured at 29 V. The detector output signal was sequentially amplified by a charge sensitive preamplifier (Kromek Ltd, ev-550/ev-5094) and a shaping (Ortec, 572A) amplifier with a gain of 1000× and shaping time of 6 μs, then record by an MCA (Ortec, easy-MCA). The charge sensitive preamplifier was not used when the SiPM was used as detector. For temperature dependent γ-ray spectra collection, the detectors coupled with scintillator were put in a muffle furnace, and spectra were collected after holding them at set temperature for 30 min.

### VII. Stability Measurement

The dark count rate stability, photon response stability and pulse detection probability stability were conducted by the same system as photon counting performance measurement. The output histogram was acquired with 10 s continuous recording followed by an interval of 50 s. For photon response stability and pulse detection probability stability, the light continuously illuminated the devices during the measurement. For long-term stability, the ¹³⁷Cs γ-ray spectrum was collected once per week using the same perovskite PCD coupled with the CsI(Tl) scintillator under the same experimental conditions.

### Example 1—Origins of Dark Counts in Perovskite Photodetectors

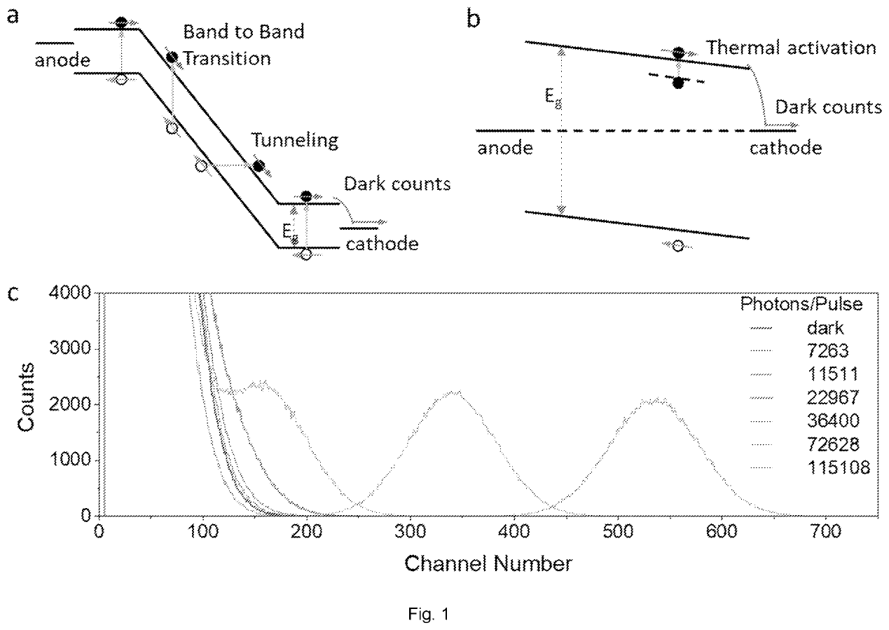

Understanding the origin of the dark counts in SiPMs enables the design the photodetectors to reduce dark count rate (DCR). As shown in FIG. 1A, the DCR of SiPMs operating at high bias is dominated by band-to-band thermally generated carriers, and band-to-band tunneling.¹⁰ Free charge carriers are frequently thermally generated and then accelerated by the large electric field in avalanche zone, causing dark counts even without incident photons. In addition, the large electric field in SiPMs can cause the direct tunneling of electrons from valance band to conduction band, which dominates the noise at temperature below 200 K.¹¹ In this study, methylammonium lead iodide (MAPbI₃) and methylammonium-formamidinium mixed cation perovskites (FA_{0.7}MA_{0.3}PbI₃) were chosen for the self-powered PCDs because of their wider bandgap of >1.5 eV while maintaining the detection capability for UV-visible light. The free carrier concentration caused by thermal excitation is 6-7 orders of magnitude smaller than that of silicon for the above perovskites. The defect tolerance of perovskites may enable efficient charge extraction even at very low density of photoinduced charges. The perovskite PCDs are operated in photovoltaic mode at zero bias, i.e. the photo-generated carriers are extracted by the built-in field. The zero bias operation simplifies the read-out electronics and avoid the issue of ion migration. The DCR of perovskite PCDs may be dominated by the thermal de-trapping of trapped charges, as illustrated in FIG. 1B.

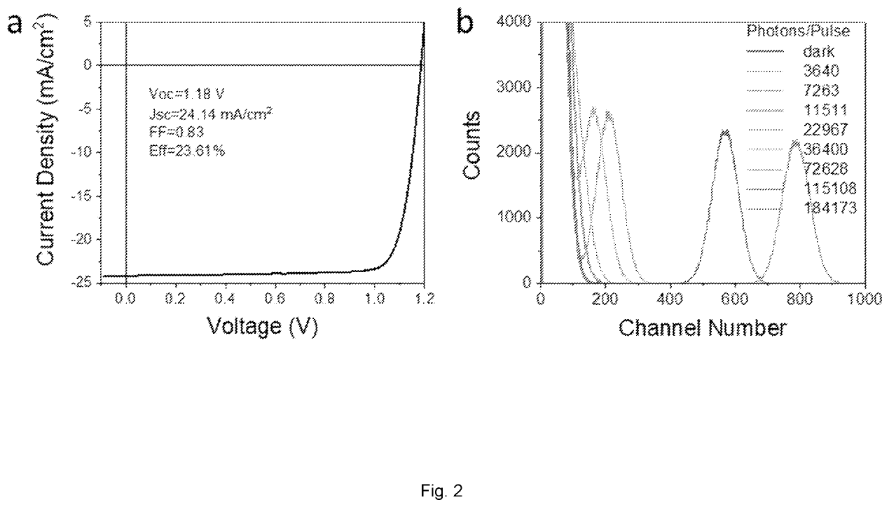

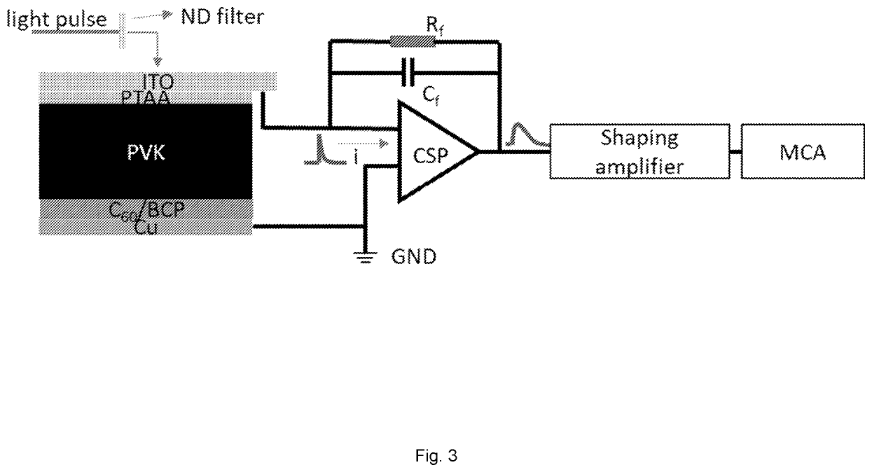

The perovskite PCDs in this study have the same device structure as regular p-i-n perovskite solar cells having the structure indium tin oxide (ITO)/poly(bis(4-phenyl) (2,4,6-trimethylphenyl)amine) (PTAA)/perovskite/C60/bathocuproine (BCP)/copper (Cu). The perovskite layer was either deposited by a one-step spin-coating followed by an antisolvent treatment (referred to in later experiments as one-step or one-step PCDs), or using a blading process followed by drying with a nitrogen knife, which can yield an efficiency of ˜23.6% for FA_{0.7}MA_{0.3}PbI₃ using optimized additives and fabrication conditions.¹³ The photocurrent density-voltage curve (J-1) of one typical perovskite device is shown in FIG. 2A. The photon counting capability was evaluated using a measurement setup illustrated in FIG. 3, consisting of a 630 nm picosecond pulsed laser, neutral density filters, a charge sensitive preamplifier (CSP), a shaping amplifier, and a multichannel analyzer (MCA). The incident photon number to PCDs was controlled by neutral density filters, and output pulse signal from PCDs was sequentially amplified, then recorded by MCA, resulting in histograms of photon counts. The FA_{0.7}MA_{0.3}PbI₃ and MAPbI₃ perovskite devices showed a high DCR of 23467 and 23732 cps/mm², respectively, even though the devices were operating at zero bias. The minimal detectable photon number for each perovskite PCD, which is defined by the incident photon number that results in a histogram distinguishable from the noise, was 11511 and 22967 respectively, as shown in FIG. 2B and FIG. 1C. This performance is still too poor for PCDs to be used in application of gamma (γ)-rays quanta detection. For example, a cesium iodide tritium (CsI(Tl)) scintillator exposed to ⁵⁷Co (122 keV) γ-ray quanta generates 6588 photons. The very large DCR cannot be explained by band-to-band transition in MAPbI₃ given its relatively large bandgap, suggesting that the dark current was likely caused by thermally activated charge carriers from charge traps.

### Example 2—Impact of Surface Passivation on DOR

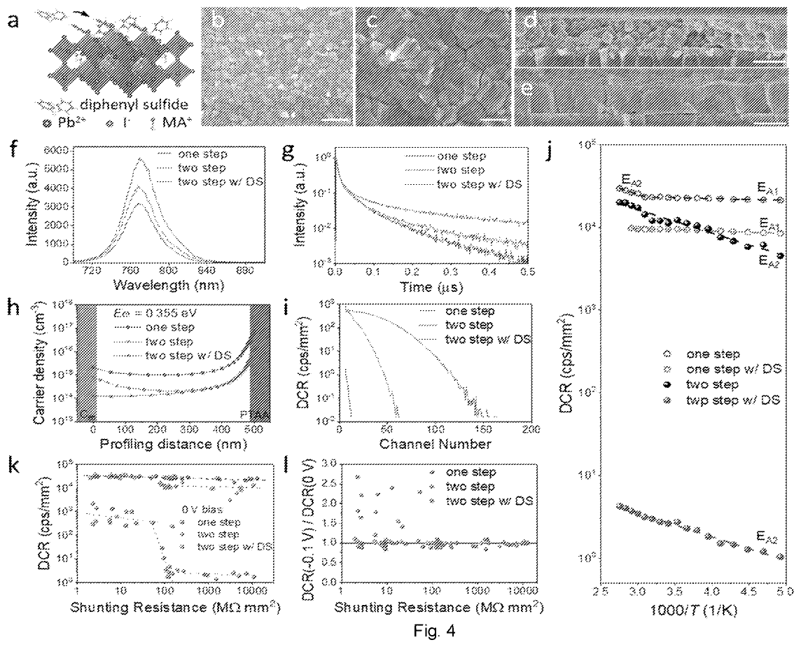

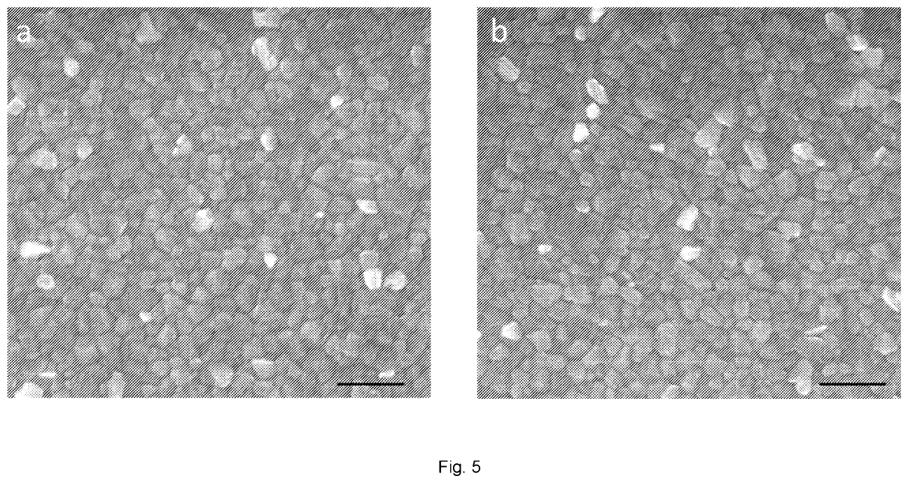

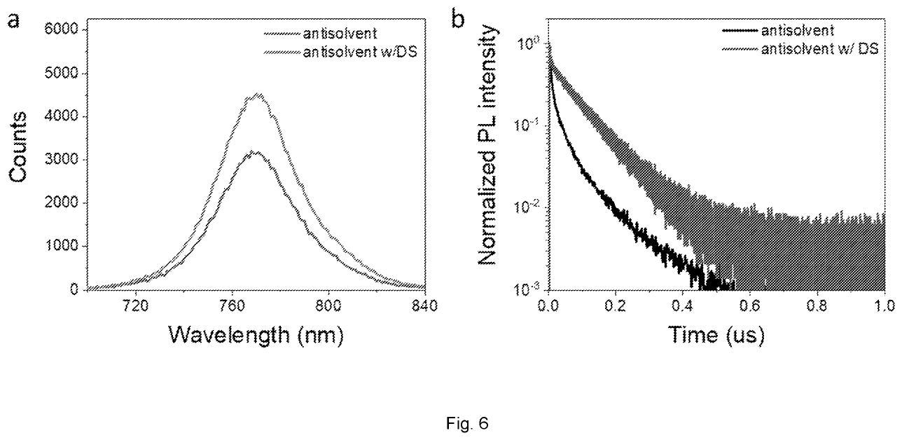

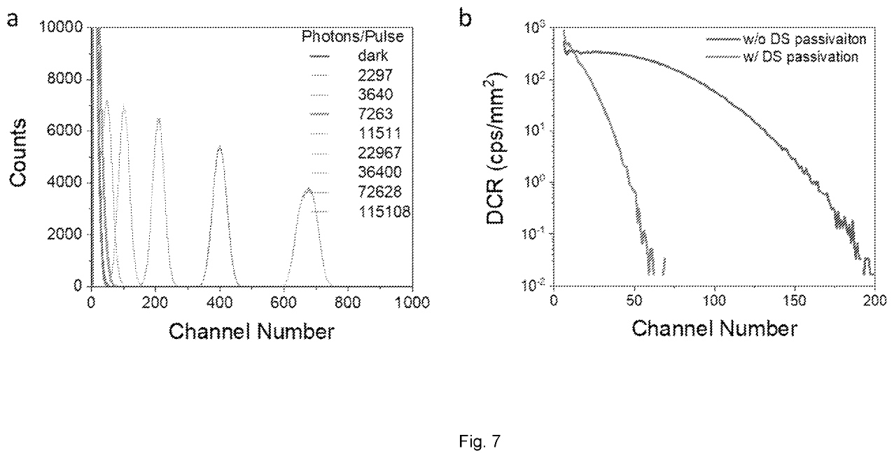

Prior studies showed that the deep-trapping defects are mainly located at the film surface. 26-28 To find out how such defects impact the DCR, the surface of MAPbI₃ was passivated with diphenyl sulfide (FIG. 4A). Here diphenyl sulfide was chosen for surface passivation because of the relatively strong coordination of sulfur with lead. The S—Pb coordination using diphenyl sulfide is not as strong as coordination with ionic sulfur (S²⁻) and thus does not pull Pb out of the octahedral structure. The surface passivation was conducted by spin-coating or blading a very thin layer of diphenyl sulfide onto perovskite surface, which is evidenced by the maintained perovskite morphology after surface treatment (FIG. 5). In other words, unlike ionic sulfur (S²⁻), the S—Pb coordination using diphenyl sulfide is not as strong and thus has relatively lower tendency to pull Pb out of the octahedral structure, which is evidenced by the maintained perovskite morphology after surface treatment. Both steady-state photoluminescence (PL) and transient PL (TRPL) measurement confirm that surface passivation is effective by the 44% stronger PL intensity and 36% longer PL lifetime (FIG. 6). However, the DCR was only reduced by 2.8 times after this surface treatment (FIG. 7), indicating these one step films still have a large density of defects in the bulk of the grains, at grain boundaries, or at the embedded bottom interfaces.

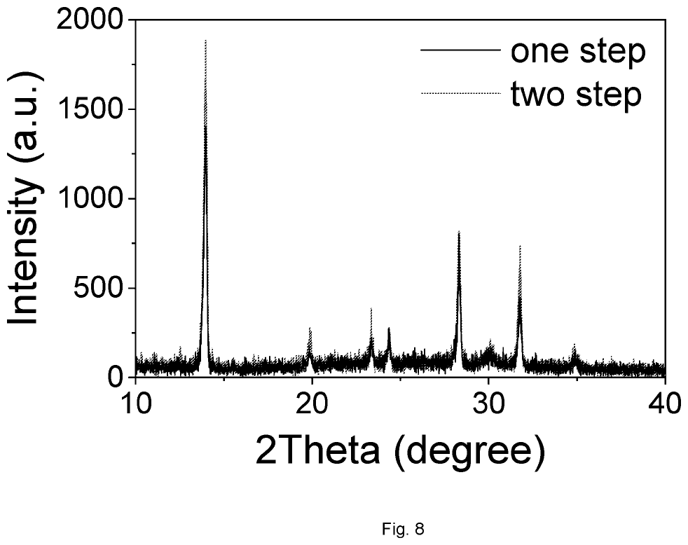

Alternatively, perovskites were deposited using a two-step process (referred to in later experiments as two-step or two-step PCDs). Previously reported studies showed that a two-step process enables the formation of monolithic grains without many horizontal grain boundaries so that charges can be directly collected without encountering defective grain boundaries.^{29, 30} PbI₂ was first deposited on the hole transport layer (HTL), such as PTAA, and then MAI was coated sequentially, followed by a thermal annealing to facilitate interdiffusion into each other to form perovskites.³¹ An ultra-thin polymethyl methacrylate (PMMA) was introduced between the perovskite and PTAA layers to passivate the defects at the embedded interface. 32.33 As shown by the scanning electron microscope (SEM) images in FIGS. 4B and 4C, the average grain size increased from 129 nm to 331 nm when using the two-step process. The larger perovskite grain size was clearly observed in the cross-sectional SEM images of the MAPbI₃ film (FIG. 4E), showing monolithic grains. The X-ray diffraction (XRD) pattern in FIG. 8 also shows that the two-step processed films have higher XRD peak intensity and sharper diffraction peaks, suggesting a better crystallinity. The two-step processed film showed 30% stronger PL intensity than the one-step processed film, and the PL lifetime of 155 ns for the two-step processed film is much longer than one-step processed film (64 ns), indicating less defects in two-step MAPbI₃ films.

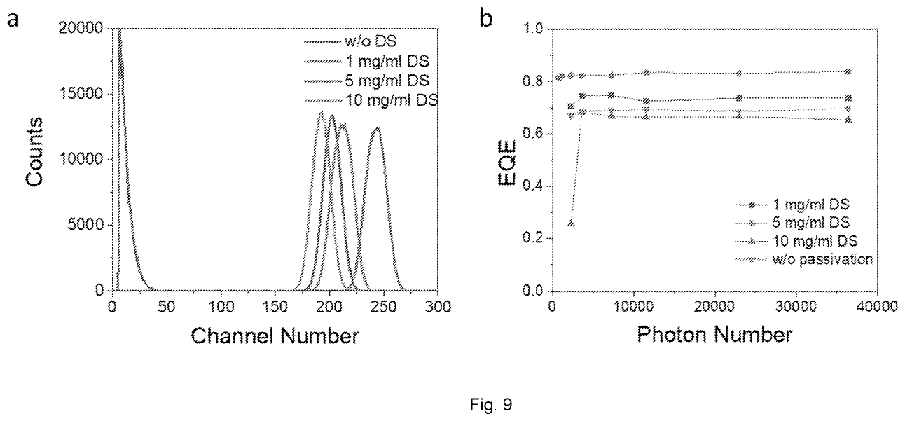

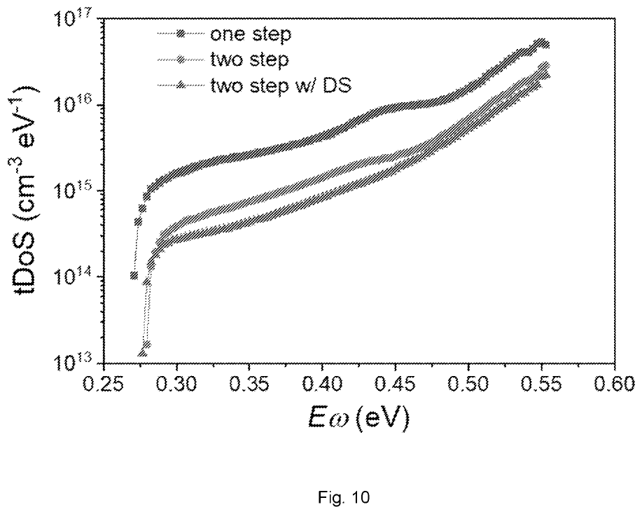

Since perovskite films made using the two-step method require a longer annealing (90 min) at a relatively high temperature, their surfaces are richer in defects due to the evaporation of MAI.^{34, 35} Therefore, surface passivation using diphenyl sulfide was also performed (referred to in later experiments as two-step with passivation). The concentration of diphenyl sulfide was optimized by controlling the solution concentration to achieve the highest charge collection efficiency based on the channel number of the photopeak (FIG. 9). The deep trap passivation effect of diphenyl sulfide was evaluated by thermal admittance spectroscopy (TAS) and optical study. After surface passivation, the PL increased by 33%, and PL lifetime increased to 869 ns, as shown in FIGS. 4F and 4G. The two-step perovskite photodetectors had ˜10 times lower trap density over the whole trap depth region than the one-step detector (FIG. 10), and the surface treatment with diphenyl sulfide further halved the trap density. Drive-level capacitance profiling (DLCP) measurement (FIG. 4H) also showed that the trap density was reduced by 9 times throughout the perovskite films using two-step method, and surface sulfurization further reduced the defect density mainly close to the surface between the perovskite and ETL. The reduction of deep charge traps is accompanied with the reduction of DCR of the perovskite PCDs, however these two properties do not show a good correlation. The integrated DCR was only reduced by half when the perovskite fabrication was changed to the two-step process, while the subsequent surface treatment dramatically reduced the integrated DCR by 6000 times to an ultra-low value of 2 cps/mm² at room temperature (FIG. 4I). This DCR is more than three orders of magnitude (10³) smaller than that of SiPMs measured in this study. The dramatic reduction of DCR came from not only the suppressed dark count rate but also the reduced amplitude of dark count events.

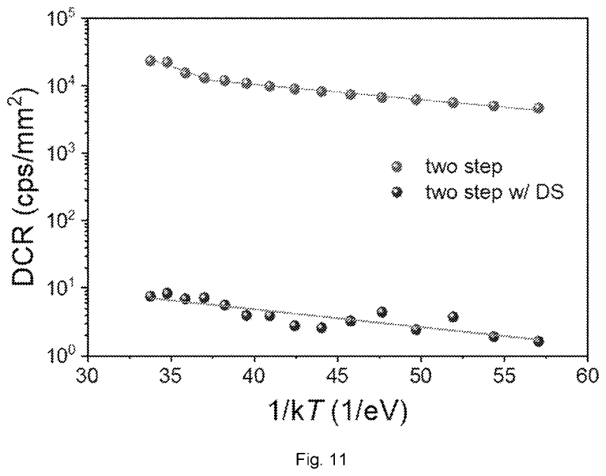

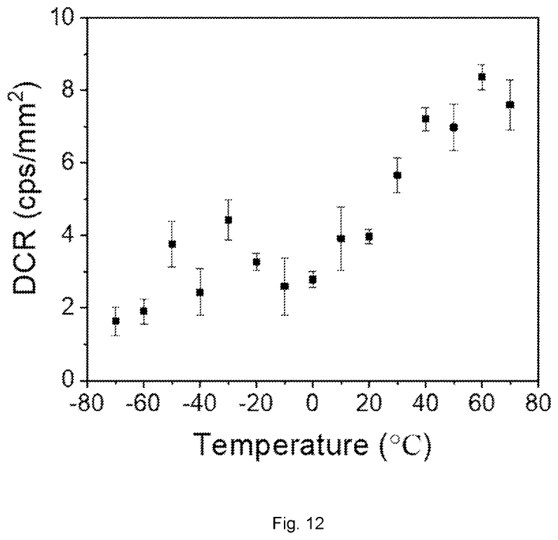

The lack of correlation between the DCR and deep trap density indicates the dark counts in perovskite PCDs may be caused by shallow traps. Calculating very shallow defects by density functional theory (DFT) would be technically difficult due to the relatively large uncertainty of energy levels from density function theory. To experimentally find out whether deep charge traps or shallow charge traps affect DCR, the temperature dependent DCR of perovskite PCDs was tested, and used to derive the activation energy of the charge traps that induce dark counts from the slope of In (DCR) ˜1/T. As shown in FIG. 4J, the one-step devices exhibited very shallow traps with an activation energy of 5.8±0.8 meV (E_{A1}). These traps are so shallow that their thermal excitation at room temperature can easily reemit all trapped charges to the conduction band, thus explaining the very large DCR in these films. Traps with activation energy of ˜57 meV (E_{Λ2}) start to contribute to DCR at higher temperature of 50° C. The 5.8 meV traps may mainly arise from defects at grain boundaries given that surface passivation only slightly reduced the DCR. The surface passivation eliminated the traps of 57 meV, indicating that these traps are located at film's surface. The trap location assignment is further supported by the disappearance of the ultra-shallow traps after the size of grains in perovskite films was enhanced by synthesis using the two-step process. Instead, the two-step perovskite film has a dominating charge trap level with a depth of 57.2±0.1 meV. The density of this trap level was dramatically reduced by surface passivation using diphenyl sulfide, which again demonstrates that this defect is mainly located at the film's surface. In some of the two-step perovskite films that were annealed for a longer period, deep traps with a E_{A3} of ˜190 meV were observed (FIG. 11), which were also successfully passivated by diphenyl sulfide. This study concludes that the dark counts in perovskite PCDs are dominated by shallow charge traps either at grain boundaries or films surface, rather than deep ones, as deep traps will not re-emit the trapped charges within the time range of detection used herein. Additionally, while these shallow traps do not impact the efficiency of corresponding perovskite solar cells, they are detrimental to perovskite PCDs due to the higher dark counts. Due to the small activation energy of charge traps, the DCR of the passivated perovskite PCDs only changed from ˜8 cps/mm² to ˜2 cps/mm² at the temperature range of from −70° C. to 70° C. (FIG. 12). This lack of variability due to temperature is a very desired property in applications such that temperature controlling of perovskite PCDs is not needed. This further confirms that the de-trapping of trapped charges from shallow traps causes the dark counts in photon-counting modes, and the two-step fabrication process in combination with surface sulfurization is effective in reducing the shallow traps in perovskite films. In this context, the difficulty of doping perovskites, in striking contrast of many other inorganic semiconductors, contributes to the very low DCR of the perovskite PCDs.

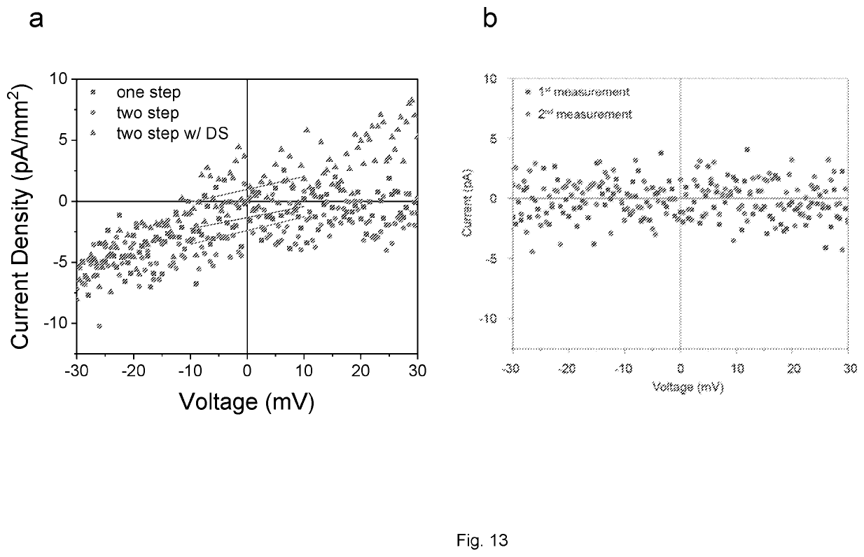

Although the average dark current of the devices operating at zero bias is zero, the fluctuation of dark current may still contribute to DCRs if the solution-processed devices are shunted, defined above. The correlation between devices shunting resistance and DCR by measuring 32 one-step devices, 30 two-step devices, and 32 two-step devices with passivation was investigated. Some of these devices showed obvious shunting behavior due to non-optimized fabrication process, but were still measured to find out the impact of shunting to DCRs. The shunting resistance was determined by the inverse slope of the J-V curves at the 0 V point,³⁶ as illustrated in FIG. 13. As shown in FIG. 4K, all the three types of devices showed a large variation of shunting resistance from a few MΩ mm² to >10,000 MΩ mm². The DCRs of all one-step devices are very high (27941±3561 cps/mm²) and reduce minimally with the increase of shunting resistance, indicating that the charge de-trapping from shallow traps dominates the DCR. For two-step devices, DCR is ˜32020±4584 cps/mm² for devices with shunting resistances less than 49.5 MΩ mm², and slightly drops to 11103±3358 cps/mm² for devices with shunting resistance above 180 MΩ mm². The shallow trap density is still large enough that the contribution from shunting is dimed even among the devices with very small shunting resistance. For the two-step devices with passivation, the de-trapping induced dark counts is significantly suppressed so that the impact of shunting to DCRs became clearer: the DCR is 753±579 cps/mm² for the devices with shunting resistance less than 53 MΩ mm², and the DCR declines with the increase of shunting resistance. The DCR sharply reduced to an almost constant value of 2.1±1.0 cps/mm² for devices with shunting resistance above 146 MΩ mm², indicating that the DCR is only determined by de-trapping process. Furthermore, a small bias of −0.1 V was applied to the devices which should increase shunting due to the increased leakage current but have negligible impact to the charge de-trapping process. FIG. 4L showed the ratio of DCRs of each device measured at −0.1 V and 0 V. The DCR ratio equals to 1 when the DCR is dominated by charges de-trapping process, and exceeds 1 when shunting dominates, which is consistent with the above hypothesis. It further confirms that the DCRs of the optimized perovskite PCDs are caused by shallow traps.

### Example 3—Photon Counting Performance of Zero Bias Perovskite PCDs

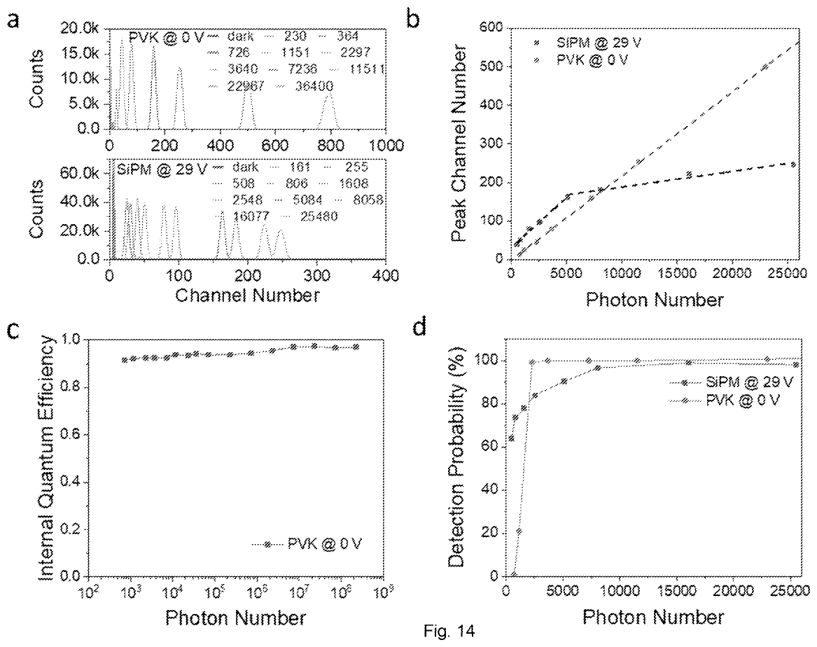

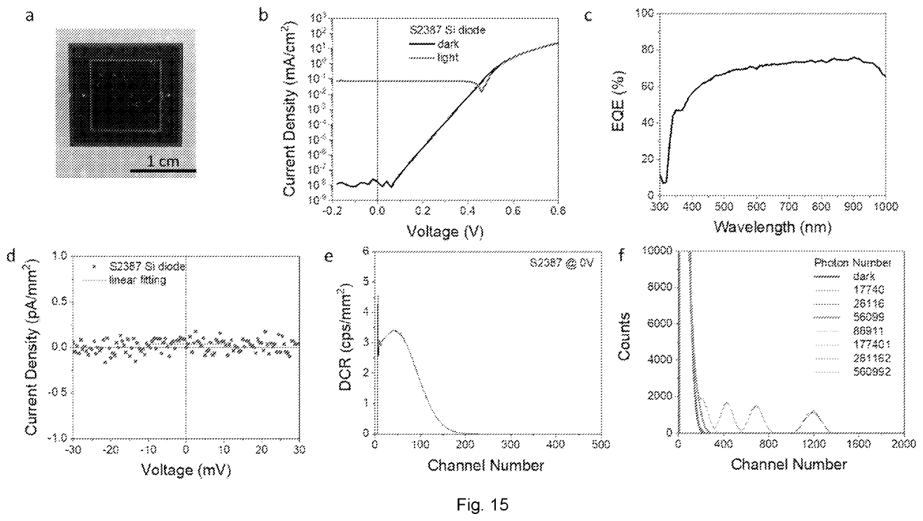

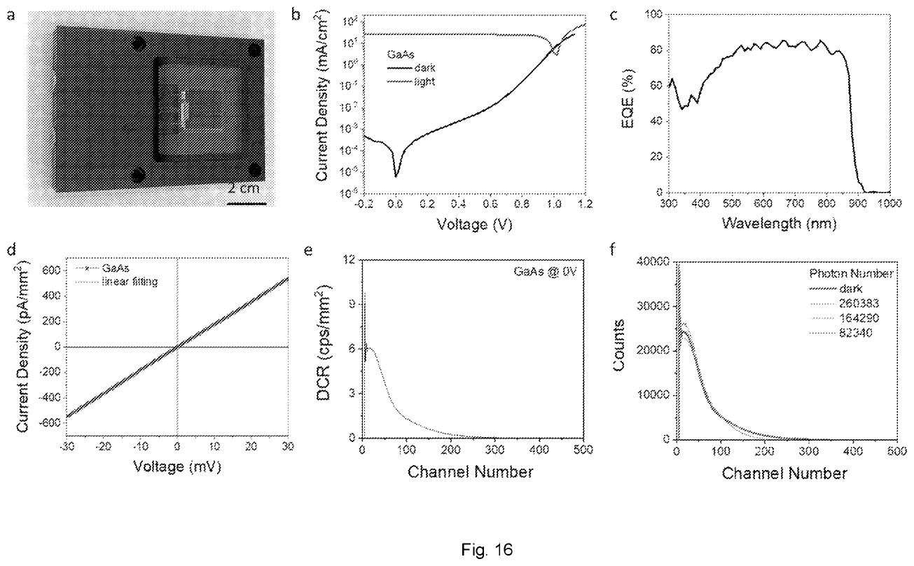

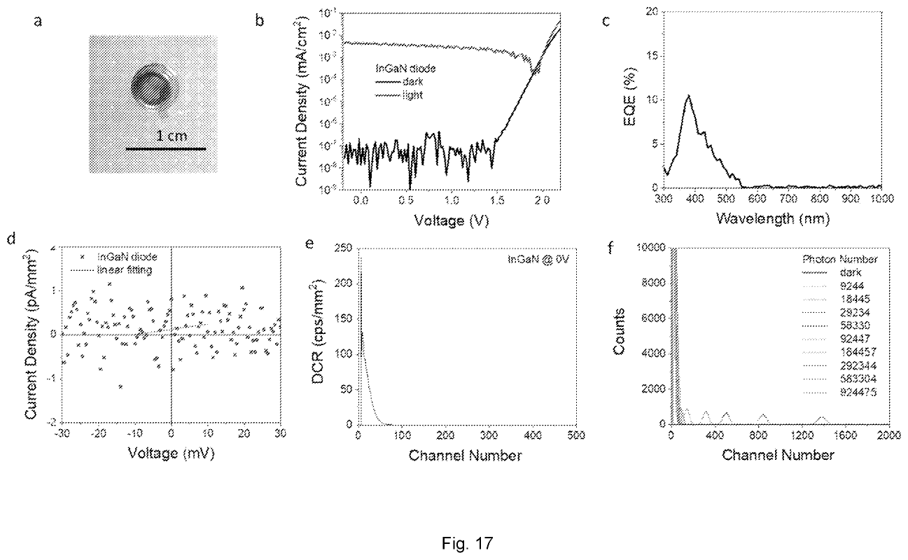

The photon counting performance of the zero-biased perovskite PCDs was further examined and compared with a commercial SiPM operated at 29 V, and commercial single crystalline Si, GaAs and InGaN photodiodes at 0 V. GaAs and InGaN have a comparable or a much larger bandgap than the perovskite used here so that thermal noise contribution is very small. The output histograms of them are shown in FIG. 14A (SiPM) and FIGS. 15-17 (Si diode, GaAs photodiode, and InGaN photodiode, respectively). The photopeak shifted toward smaller channel number when the incident photon number decreased for both perovskite PCD and the SiPM. The perovskite PCD demonstrated the minimal detectable photon number of 726, which is good enough to count the photons from CsI(Tl) scintillator exposed to ⁵⁷Co γ-rays. The Si photodiode showed ˜100 times larger DCR than the perovskite PCD, and a minimal detectable photon number of 56,099, despite that its shunting resistance is ˜100 times larger. The GaAs photodiode could not do photon counting, because a huge incident photon number of 260,383 per pulse did not generate any signal. The InGaN diode showed a DCR that is ˜1000 times larger than that of perovskite devices despite of the huge shunting resistance and wider bandgap, and a minimal detectable photon number of 29,234. These results show that perovskite PCDs are superior to typical inorganic crystalline photodiodes for photon counting application, bolstered by their unusual defect tolerance and low density of shallow traps after passivation.

SiPM can do photon-counting, but with inferior performance. The linearity of the SiPM and perovskite PCDs was derived by plotting the photopeak channel number with the number of incident photons. The SiPM showed two linear regions, limiting its photon counting capability (FIG. 14B). In striking contrast, the perovskite PCD had a good linearity in the same range. To evaluate the linearity response at a wider range, the internal quantum efficiency (IQE), defined by the number of charges collected by the device per absorbed photon, was evaluated with up to 229 million photons per light pulse. The IQE was derived from the external quantum efficiency (EQE) and the reflectance (R) of the detector at the same wavelength based on IQE=EQE/(1−R). The perovskite PCD had a constant IQE of 95±5% from 726 photons to >10⁸ photons, as shown in FIG. 14C. The huge linear dynamic range of the perovskite PCD should be ascribed to the low deep defect density, which contributes to the good linear response under weak light, and low charge recombination in perovskites, which contributes to the linear response under strong light. The pulse detection probability, defined as the probability that an incident light pulse generates an output pulse, was directly measured for perovskite and SiPM PCDs. As shown in FIG. 14D, the pulse detection probability of the SiPM increased from 73.8% to 96.6% when the incident photons per pulse increased from 806 to 8058 and saturated at ˜99% for stronger light pulse. In striking contrast, the perovskite detector exhibited a nearly constant pulse detection probability of >99.8% when each light pulse has 1600 or more photons. Therefore, perovskite PCDs can count ˜15% more pulses than the SiPM when photon number per event is less than 8058.

### Example 4—Application of Perovskite PCDs as Gamma(?) Ray Detector

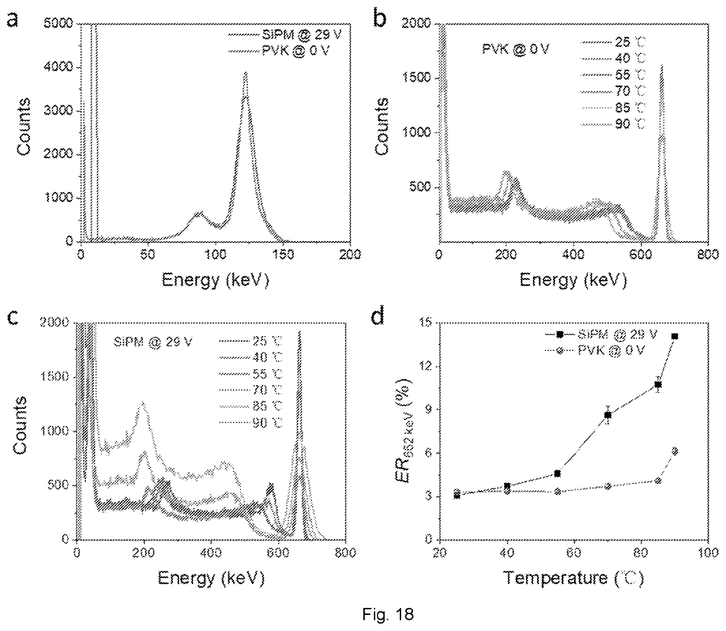

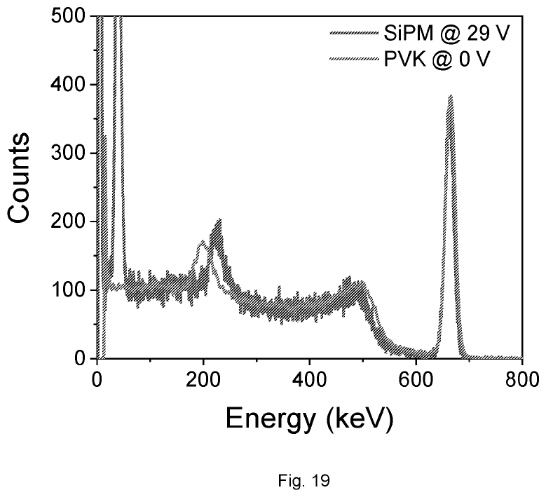

The demonstrated photon counting capability of the perovskite PCDs makes them a promising candidate as γ-ray spectrum detector in combination with a scintillator. Here, we coupled perovskite PCDs with a cerium doped lanthanum bromide (LaBr₃:Ce) scintillator with dimensions of Φ10×14 mm³. LaBr₃:Ce is one of the brightest scintillators with a light output of 68 photons/keV and emission centered around 380 nm, well matched with the response spectrum of perovskite PCDs. The ⁵⁷Co γ-ray energy spectra collected by the SiPM and the perovskite PCD under the same conditions were showed in FIG. 18A. The perovskite PCD showed 16.3% more counts during the same acquisition time, and the energy resolution of 9.3±0.17% at 122 keV is better than that of the SiPM (11.34±0.27%). For high energy γ-ray photons, the perovskite PCDs gave a comparable energy resolution of 3.2±0.1% at 662 keV (FIG. 19), which can be explained by their comparable photon counting probability under strong light. To evaluate the capability of the PCDs at harsh environment, ¹³⁷Cs γ-ray energy spectra were collected by the perovskite and the SiPM PCDs by putting the PCDs and scintillator in a muffle furnace with controlled temperature from 25° C. to 90° C. As shown in FIG. 18B, the spectra collected by the perovskite PCD almost overlapped when temperature was lower than 70° C. The photopeak broadened slightly when the temperature further increased, which may be caused by the reduced light yield of LaBr₃:Ce at higher temperature³⁷, while the photopeak broadening was very small at the temperature <90° C. In contrast, the energy resolution of the spectra collected by the SiPM obviously changed from 3.1% to above 10% when the temperature increased to above 85° C. (FIGS. 18C and 18D). This clearly shows the advantage of perovskite PCDs in working at much harsher environment benefiting from the negligible change of DCR and charge collection efficiency to temperature.

### Example 5—Response Stability of Perovskite PCDs

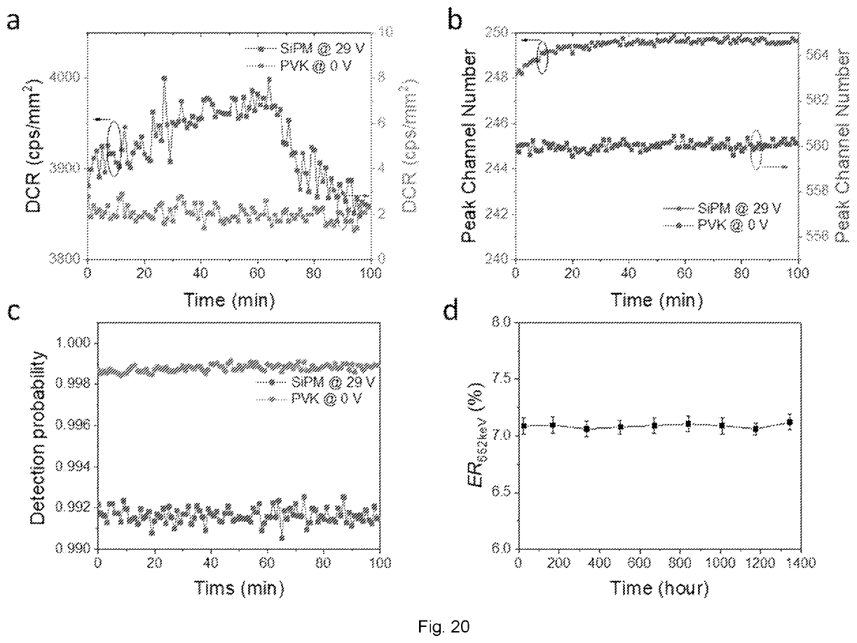

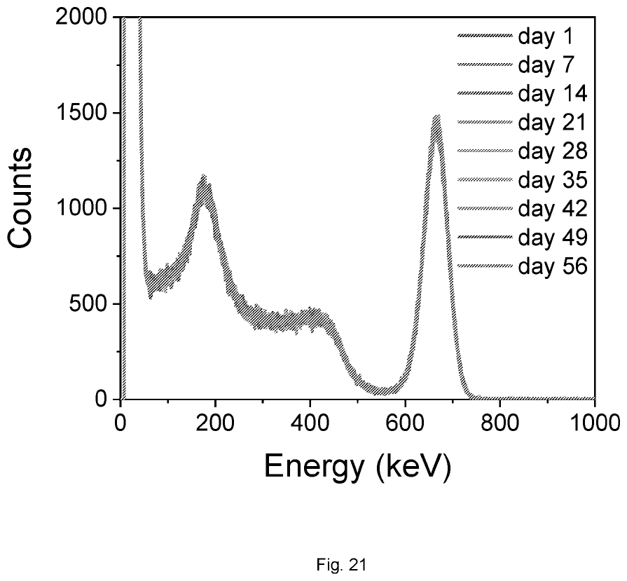

Operating the perovskite PCDs at zero bias also brings the unprecedented small drift of device performance over time, because it avoids the large electric field induced device degradation or material change. To demonstrate that, the DCR of the perovskite detector at zero bias and the SiPM at 29 V were acquired for multiple cycles without temperature controlling, and the DCR was calculated from the total counts in each cycle divided by the acquisition time (FIG. 20A). The DCR of the SiPM is not only high, but also fluctuated by 185 cps/mm², which may be related to the minor temperature fluctuation of the environment. In striking contrast, the perovskite PCD exhibited a nearly constant and very small DCR of 2 cps/mm². The response stability of the PCDs was measured by illuminating them with light pulses. The SiPM output photopeak channel number drifted from 248 to 250 after 30 min, while the perovskite PCDs had nearly no drifting (FIG. 20B). The pulse detection probability of the PCDs was tracked for 100 min. The perovskite PCD and the SiPM have pulse detection probability of 99.97±0.02% and 99.16±0.37% respectively (FIG. 20C). In addition, the long-term stability was evaluated by tracking the ¹³⁷Cs γ-ray spectrum energy resolution, and the ¹³⁷Cs γ-ray spectrum was collected once per week. As shown in FIG. 20D, the energy resolution at 662 keV kept unchanged within 8 weeks for the perovskite PCD, and the measured spectra almost overlapped (FIG. 21).

In summary, we found that the DCR of perovskite PCDs was dominated by charge detrapping from shallow traps located at the grain boundaries and surface, and the ultra-low DCR was achieved by suppressing the shallow traps by enhancing grain size and passivating film surface with diphenyl sulfide. The suppression of shallow traps made the perovskite PCDs have 100-1000 times lower DCR and much better response linearity to weak light than SiPMs, and the DCR was not sensitive to temperature due to small activation energy of charge traps. The zero-bias operating perovskite PCDs were demonstrated as γ-ray spectrum detectors with better energy resolution under ⁵⁷Co source than commercial SiPMs at room temperature. At higher temperature up to 85° C.′, the perovskite PCDs are much superior to SiPMs by maintaining the energy resolution, showing their potential of working in harsh environment. This study discovered regular surface passivation also dramatically impact shallow charge traps, which should have implication of perovskite stability and doping.

Efforts have been made to ensure accuracy with respect to numbers used (e.g., amounts, temperature, etc.) but some experimental errors and deviations should be accounted for.

One skilled in the art will recognize many methods and materials similar or equivalent to those described herein, which could be used in the practicing the subject matter described herein. The present disclosure is in no way limited to just the methods and materials described.

Unless defined otherwise, technical, and scientific terms used herein have the same meaning as commonly understood by one of ordinary skill in the art to which this subject matter belongs.

Throughout this specification and the claims, the words “comprise,” “comprises,” and “comprising” are used in a non-exclusive sense, except where the context requires otherwise. It is understood that embodiments described herein include “consisting of” and/or “consisting essentially of” embodiments.

Where a range of values is provided, it is understood that each intervening value, to the tenth of the unit of the lower limit, unless the context clearly dictates otherwise, between the upper and lower limit of the range and any other stated or intervening value in that stated range, is encompassed. The upper and lower limits of these small ranges which may independently be included in the smaller rangers is also encompassed, subject to any specifically excluded limit in the stated range. Where the stated range includes one or both of the limits, ranges excluding either or both of those included limits are also included.

Many modifications and other embodiments set forth herein will come to mind to one skilled in the art to which this subject matter pertains having the benefit of the teachings presented in the foregoing descriptions and the associated drawings. Therefore, it is to be understood that the subject matter is not to be limited to the specific embodiments disclosed and that modifications and other embodiments are intended to be included within the scope of the appended claims. Although specific terms are employed herein, they are used in a generic and descriptive sense only and not for purposes of limitation.

### REFERENCES

1 Gundacker, S. & Heering, A. The silicon photomultiplier: fundamentals and applications of a modern solid-state photon detector. Physics in Medicine & Biology 65, 17TR01 (2020).
2 Ye, M. et al. Lightweight SiPM-based CeBr3 gamma-ray spectrometer for radiation-monitoring systems of small unmanned aerial vehicles. Applied Radiation and Isotopes 176, 109848 (2021).
3 Agishev, R. et al. Lidar with SiPM: some capabilities and limitations in real environment. Optics & Laser Technology 49, 86-90 (2013).
4 Hadfield, R. H. Single-photon detectors for optical quantum information applications. Nature Photonics 3, 696-705 (2009).
5 Eraerds, P., Legre, M., Rochas, A., Zbinden, H. & Gisin, N. SiPM for fast photon-counting and multiphoton detection. Optics Express 15, 14539-14549 (2007).
6 Del Guerra, A. et al. Advantages and pitfalls of the silicon photomultiplier (SiPM) as photodetector for the next generation of PET scanners. Nuclear Instruments and Methods in Physics Research Section A: Accelerators, Spectrometers, Detectors and Associated Equipment 617, 223-226 (2010).
7 Buzhan, P. et al. in Advanced technology and particle physics 717-728 (World Scientific, 2002).
8 Du, J. et al. Characterization of large-area SiPM array for PET applications. IEEE transactions on nuclear science 63, 8-16 (2016).
9 Engelmann, E., Popova, E. & Vinogradov, S. Spatially resolved dark count rate of SiPMs. The European Physical Journal C 78, 1-8 (2018).
10 Panglosse, A. et al. Dark count rate modeling in single-photon avalanche diodes. IEEE Transactions on Circuits and Systems I: Regular Papers 67, 1507-1515 (2020).
11 Liu, F. et al. Characterization of a mass-produced SiPM at liquid nitrogen temperature for CsI neutrino coherent detectors. Sensors 22, 1099 (2022).
12 Fleck, I., Titov, M., Grupen, C. & Buvat, I. Handbook of Particle Detection and Imaging. (Springer, 2019).
13 Chen, S. et al. Stabilizing perovskite-substrate interfaces for high-performance perovskite modules. Science 373, 902-907 (2021).
14 Lin, K. et al. Perovskite light-emitting diodes with external quantum efficiency exceeding 20 percent. Nature 562, 245-248 (2018).
15 Fang, Y., Dong, Q., Shao, Y., Yuan, Y. & Huang, J. Highly narrowband perovskite single-crystal photodetectors enabled by surface-charge recombination. Nature Photonics 9, 679-686 (2015).
16 Zhao, J. et al. Perovskite-filled membranes for flexible and large-area direct-conversion X-ray detector arrays. Nature Photonics 14, 612-617 (2020).
17 Luo, J. et al. Water photolysis at 12.3% efficiency via perovskite photovoltaics and Earth-abundant catalysts. Science 345, 1593-1596 (2014).
18 Deng, Y. et al. Tailoring solvent coordination for high-speed, room-temperature blading of perovskite photovoltaic films. Science advances 5, eaax7537 (2019).
19 Ávila, J., Momblona, C., Boix, P. P., Sessolo, M. & Bolink, H. J. Vapor-deposited perovskites: the route to high-performance solar cell production? Joule 1, 431-442 (2017).
20 Dong, Q. et al. Electron-hole diffusion lengths>175 μm in solution-grown CH₃NH₃PbI₃ single crystals. Science 347, 967-970 (2015).
21 Wei, H. et al. Sensitive X-ray detectors made of methylammonium lead tribromide perovskite single crystals. Nature Photonics 10, 333-339 (2016).
22 Stranks, S. D. et al. Electron-hole diffusion lengths exceeding 1 micrometer in an organometal trihalide perovskite absorber. Science 342, 341-344 (2013).
23 Shi, D. et al. Low trap-state density and long carrier diffusion in organolead trihalide perovskite single crystals. Science 347, 519-522 (2015).
24 Bao, C. et al. Low-noise and large-linear-dynamic-range photodetectors based on hybrid-perovskite thin-single-crystals. Advanced Materials 29, 1703209 (2017).
25 Fang, Y. & Huang, J. Resolving weak light of sub-picowatt per square centimeter by hybrid perovskite photodetectors enabled by noise reduction. Advanced Materials 27, 2804-2810 (2015).
26 Chen, S. et al. Identifying the soft nature of defective perovskite surface layer and its removal using a facile mechanical approach. Joule 4, 2661-2674 (2020).
27 Li, X. et al. Constructing heterojunctions by surface sulfidation for efficient inverted perovskite solar cells. Science 375, 434-437 (2022).
28 Wu, W.-Q. et al. Reducing surface halide deficiency for efficient and stable iodide-based perovskite solar cells. Journal of the American Chemical Society 142, 3989-3996 (2020).
29 Shen, L. et al. A self-powered, sub-nanosecond-response solution-processed hybrid perovskite photodetector for time-resolved photoluminescence-lifetime detection. Advanced Materials 28, 10794-10800 (2016).
30 Shen, L. et al. Integration of perovskite and polymer photoactive layers to produce ultrafast response, ultraviolet-to-near-infrared, sensitive photodetectors. Materials Horizons 4, 242-248 (2017).
31 Lee, J.-W. & Park, N.-G. Two-step deposition method for high-efficiency perovskite solar cells. MRS Bulletin 40, 654-659 (2015).
32 Zhang, F. et al. Comprehensive passivation strategy for achieving inverted perovskite solar cells with efficiency exceeding 23% by trap passivation and ion constraint. Nano Energy 89, 106370 (2021).
33 Wang, J. et al. Front-contact passivation of PIN MAPbI₃ solar cells with superior device performances. ACS Applied Energy Materials 3, 6344-6351 (2020).
34 Turren-Cruz, S.-H., Hagfeldt, A. & Saliba, M. Methylammonium-free, high-performance, and stable perovskite solar cells on a planar architecture. Science 362, 449-453 (2018).
35 Zheng, X. et al. Defect passivation in hybrid perovskite solar cells using quaternary ammonium halide anions and cations. Nature Energy 2, 1-9 (2017).
36 Thompson, P. R. & Larason, T. C. in Measurement Science Conference.
37 Choi, Y., Kim, K. J., Park, K. & Kim, Y. A LaBr₃ (Ce) detector system with a simple spectral shift correction method for applications in harsh environments. Radiation Measurements 142, 106567 (2021).

1. A multilayer perovskite composite comprising:
a polycrystalline perovskite film comprising a composition of Formula (I): 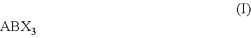
wherein A is a cation selected from the group consisting of methylammonium (MA), tetramethylammonium (TMA), formamidinium (FA), cesium (Cs), rubidium (Rb), potassium (K), sodium (NA), butylammonium (BAH), phenylethylammonium (PEA), phenylammonium (PHA), guanidinium (GU), and a combination thereof;
B is at least one divalent metal; and
X is at least one halide;
and,
a passivating layer disposed on at least a portion of a surface of said polycrystalline perovskite film;
wherein said passivating layer comprises an organosulfide material.

2. The multilayer perovskite composite of claim 1, wherein B is selected from the group consisting of lead, tin, cadmium, germanium, zinc, nickel, platinum, palladium, mercury, titanium and silicon, or a combination thereof.

3. The multilayer perovskite composite of claim 2, wherein B is lead or tin, or a combination thereof.

4. The multilayer perovskite composite of claim 3, wherein B is lead.

5. The multilayer perovskite composite of claim 1, wherein A is selected from the group consisting of methylammonium (MA), formamidinium (FA), and cesium (Cs), or a combination thereof.

6. The multilayer perovskite composite of claim 5, wherein A is methylammonium (MA).

7. The multilayer perovskite composite of claim 5, wherein A is methylammonium (MA) and formamidinium (FA).

8. The multilayer perovskite composite of claim 1, wherein X is selected from the group consisting of F, I, and Br, or a combination thereof.

9. The multilayer perovskite composite of claim 8, wherein X is I.

10. The multilayer perovskite composite of claim 1, wherein the perovskite film is selected from the group consisting of cesium lead iodide (CsPbI₃), methylammonium lead iodide (MAPbI₃), formamidinium lead bromide (FAPbI₃), methylammonium lead bromide (MAPbBr₃), formamidinium methylammonium lead iodide (FA_{0.7}MA_{0.3}PbI₃), cesium formamidinium lead iodide (Cs_{0.08}F A_{0.92}PbI₃), cesium formamidinium methylammonium lead iodide (Cs_{0.05}FA_{0.70}MA_{0.25}PbI₃), cesium formamidinium lead tin iodide (Cs_{0.2}FA_{0.8}Pb_{0.5}Sn_{0.5}I₃), cesium formamidinium lead iodide bromide (Cs_{0.2}FA_{0.8}Pb(I_{0.6}Br_{0.4})₃), and cesium methylammonium lead iodide bromide (Cs_{0.1}MA_{0.9}Pb(I_{0.9}Br_{0.1})₃).

11. The multilayer perovskite composite of claim 1, wherein the organosulfide material is a compound of Formula II: 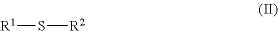
wherein R¹ and R² are each independently selected from the group consisting of (C₁-C₆) alkyl, cycloalkyl, and aryl.

12. The multilayer perovskite composite of claim 11, wherein R¹ and R² are each independently (C₁-C₆) alkyl.

13. The multilayer perovskite composite of claim 12, wherein said (C₁-C₆) alkyl is selected from the group consisting of methyl, ethyl, propyl, isopropyl, butyl, isobutyl, tert-butyl, sec-butyl, pentyl and hexyl.

14. The multilayer perovskite composite of claim 11, wherein R¹ and R² are each independently cycloalkyl or aryl.

15. The multilayer perovskite composite of claim 14, wherein R¹ and R² are each independently cycloalkyl, and wherein said cycloalkyl is selected from the group consisting of cyclopropyl, cyclobutyl, cyclopentyl, bicyclopentyl, cyclohexyl, cycloheptyl, spirocycloheptyl, and cyclooctane.

16. (canceled)

17. The multilayer perovskite composite of claim 14, wherein R¹ and R² are each independently aryl, and wherein said aryl is selected from the group consisting of phenyl, naphthalyl, tolyl, and xylyl.

18. The multilayer perovskite composite of claim 11, wherein R¹ and R² are both phenyl.

19. The multilayer perovskite composite of claim 11, wherein said organosulfide material is a compound selected from the group consisting of ethyl propyl sulfide, butyl methyl sulfide, dipropyl sulfide, butyl ethyl sulfide, methyl pentyl sulfide, dibutyl sulfide, ethyl 1-octyl sulfide, dipentyl sulfide, dihexyl sulfide, diheptyl sulfide, dioctyl sulfide, ethyl isopropyl sulfide, diallyl sulfide, diisopropyl sulfide, tert-butyl ethyl sulfide, methyl tert-butyl sulfide, isopropyl propyl sulfide, methyl phenyl sulfide, phenyl vinyl sulfide, ethyl phenyl sulfide, diphenyl sulfide, di-tert-butyl sulfide, di-sec-butyl sulfide, diisobutyl sulfide, allyl phenyl sulfide, di-1-napthyl sulfide and dibenzyl sulfide.

20. The multilayer perovskite composite of claim 19, wherein said organosulfide material is diphenyl sulfide.

21.-37. (canceled)
